(19) United States
(12) Patent Application Publication
(10) Pub. No.: US 2026/0082535 A1
(43) Pub. Date: Mar. 19, 2026

(54) SRAM UNIT, METHOD FOR MANUFACTURING SRAM UNIT, COMPLEMENTARY FIELD-EFFECT TRANSISTOR, METHOD FOR MANUFACTURING COMPLEMENTARY FIELD-EFFECT TRANSISTOR, STATIC RANDOM-ACCESS MEMORY

(71) Applicant: INSTITUTE OF MICROELECTRONICS, CHINESE ACADEMY OF SCIENCES, Beijing (CN)

(72) Inventors: Huaxiang Yin, Beijing (CN); Lei Cao, Beijing (CN); Qingkun Li, Beijing (CN); Qingzhu Zhang, Beijing (CN)

(21) Appl. No.: 19/360,413

(22) Filed: Oct. 16, 2025

(30) Foreign Application Priority Data
Sep. 14, 2024 (CN) 202411296175.1
Mar. 12, 2025 (CN) 202510293829.3

(51) Int. Cl. H10B 10/00

(52) U.S. Cl. CPC H10B 10/125

(57) ABSTRACT

An SRAM unit includes a first complementary field-effect transistor (CFET), a second CFET and a third CFET. The first CFET, the second CFET and the third CFET are arranged in parallel and have parallel channel directions. The second CFET is provided between the first CFET and the third CFET. Upper transistors and lower transistors of both the first CFET and the third CFET are N-type transistors, and an upper transistor and a lower transistor of the second CFET are P-type transistors. The upper transistor of the first CFET and the lower transistor of the third CFET serve as gate transistors. That is, the function of the SRAM unit can be achieved by providing three CFETs arranged in parallel and having parallel channel directions and the upper transistor and the lower transistor in the same conductivity type.

### CROSS-REFERENCE TO RELATED APPLICATIONS

The present application claims the priority to Chinese Patent Application No. 202510293829.3, filed on Mar. 12, 2025 with the China National Intellectual Property Administration, and the priority to Chinese Patent Application No. 202411296175.1, filed on Sep. 14, 2024 with the China National Intellectual Property Administration, both of which are incorporated herein by reference in their entireties.

### FIELD

The present disclosure relates to the field of semiconductors, and in particular, to an SRAM unit, a method for manufacturing an SRAM unit, a complementary field-effect transistor, a method for manufacturing a complementary field-effect transistor, and a static random-access memory.

### BACKGROUND

With the development of semiconductor technologies, the feature size of an integrated circuit continues to be reduced. Traditional triple-gate or double-gate fin field-effect transistors (FinFET) face limitations at technology nodes below 3 nanometers (nm). Thus, nanosheet-gate all round fin field-effect transistors (Nanosheet-GAAFET) that are not limited by a 3 nm technology node are developed. Further, complementary field-effect transistors (CFET), having broken through the limitation of a 1 nm technology node, have attracted widespread attention and research.

In the conventional technology, a storage unit of a static random-access memory (SRAM) can be formed by the complementary field-effect transistors, greatly reducing the area of the static random-access memory (SRAM). Reference is made to FIG. 1, which is a schematic circuit diagram of a storage unit in a static random-access memory. Reference is made to FIGS. 2 and 3, which are schematic diagrams illustrating two structures of a storage unit in a static random-access memory. That is, at present, by changing the design of storage unit from the planar transistors to complementary field-effect transistors, the length of the storage unit is shortened from 240 nm to 76 nm, and the area of the storage unit in the static random-access memory is greatly reduced.

However, a requirement for a smaller area of the storage unit in the static random-access memory still exists.

### SUMMARY

In view of this, an SRAM unit, a method for manufacturing an SRAM unit, a complementary field-effect transistor, a method for manufacturing a complementary field-effect transistor, and a static random-access memory are provided according to the present disclosure, which can provide lateral complementary CFETs by adjusting the layout structure to reduce the area of a storage unit in the static random-access memory.

An SRAM unit is provided according to an embodiment of the present disclosure. The SRAM unit includes a first complementary field effect transistor (CFET), a second CFET and a third CFET. The first CFET, the second CFET and the third CFET are arranged in parallel, and have parallel channel directions. The second CFET is provided between the first CFET and the third CFET. Upper transistors and lower transistors of both the first CFET and the third CFET are N-type transistors, and an upper transistor and a lower transistor of the second CFET are P-type transistors.

The upper transistor of the first CFET and the lower transistor of the third CFET serve as gate transistors.

In an embodiment, the first CFET includes: a first top source, a first top drain, a first top channel structure, a first bottom source, a first bottom drain, and a first bottom channel structure.

The second CFET includes: a second top source, a second top drain, a second top channel structure, a second bottom source, a second bottom drain, and a second bottom channel structure.

The third CFET includes: a third top source, a third top drain, a third top channel structure, a third bottom source, a third bottom drain, and a third bottom channel structure.

The SRAM unit includes multiple gates. The multiple gates respectively surround a nanosheet included in the first top channel structure, a nanosheet included in the first bottom channel structure, a nanosheet included in the second top channel structure, a nanosheet included in the second bottom channel structure, a nanosheet included in the third bottom channel structure, and a nanosheet included in the third bottom channel structure.

In an embodiment, the multiple gates include a top gate that surrounds the nanosheets included in the top channel structures for the first CFET, the second CFET and the third CFET; and a bottom gate that surrounds the nanosheets included in the bottom channel structures for the first CFET, the second CFET and the third CFET.

The bottom gates of the first CFET and the second CFET are connected with each other.

The top gates of the second CFET and the third CFET are connected with each other.

In an embodiment, a first-type work function layer is provided on surfaces of multiple nanosheets included in the first top channel structure and the first bottom channel structure. A second-type work function layer is provided on surfaces of multiple nanosheets included in the second top channel structure and the second bottom channel structure. The first-type work function layer is provided on surfaces of multiple nanosheets included in the third top channel structure and the third bottom channel structure.

In an embodiment, the first-type work function layer is an N-type work function layer, and the second-type work function layer is a P-type work function layer.

In an embodiment, a ground connection layer is provided on the first bottom source. A buried power connection layer is provided between the first CFET and the second CFET. A buried ground connection layer is provided at a side of a substrate of the first CFET that is away from the second CFET. A power connection layer is provided on the second bottom drain. The buried power connection layer is electrically connected to the power connection layer, and the buried ground connection layer is electrically connected to the ground connection layer.

In an embodiment, a first storage bottom electrode is provided on the first bottom drain, and the first storage bottom electrode is electrically connected to the first bottom drain and the second bottom source.

In an embodiment, a first storage top electrode is provided on the first top drain, and the first storage top electrode is electrically connected to the first storage bottom electrode.

In an embodiment, the first storage top electrode is connected to the first top drain of the first CFET, a top gate of the second CFET and a top gate of the third CFET.

In an embodiment, a top power connection layer is provided on the second top source, and a second storage top electrode is provided on the second top drain.

In an embodiment, the second storage top electrode is connected to the third bottom source of the third CFET, a bottom gate of the first CFET, a bottom gate of the second CFET, the second top drain of the second CFET, and the third top drain of the third CFET.

A method for manufacturing an SRAM unit is provided according to an embodiment of the present disclosure. The method includes:
providing a substrate;
forming multiple stacked structures on the substrate by alternately stacking first semiconductor layers and second semiconductor layers, where in a direction perpendicular to a plane where the substrate is located, each of the stacked structures includes a buffer layer in a middle region;
etching the stacked structure, to form three fin stacks in a first direction, a second direction, and a third direction; and
processing the fin stacks in the first direction and the third direction, to form a first complementary field-effect transistor (CFET) and a third CFET, and processing the fin stack in the second direction to form a second CFET, where the second CFET is provided between the first CFET and the third CFET.

Upper transistors and lower transistors of both the first CFET and the third CFET are N-type transistors, and an upper transistor and a lower transistor of the second CFET are P-type transistors.

A method for manufacturing a complementary field-effect transistor is provided according to an embodiment of the present disclosure. The method includes:
providing a substrate, forming multiple stacked structures on a side of the substrate by alternately stacking first semiconductor layers and second semiconductor layers, where in a direction perpendicular to a plane where the substrate is located, each of the stacked structures includes a buffer layer in a middle region;
etching the stacked structures and a partial thickness of the substrate to form two fin structures, where each of the fin structures includes a top structure, a bottom structure, and a substrate structure; the top structure and the bottom structure is separated by the buffer layer, the fin structures include a first fin structure and a second fin structure, a buried power connection layer is provided between the substrate structure of the first fin structure and the substrate structure of the second fin structure, and a buried ground connection layer is provided on a side of the substrate structure of the first fin structure that is away from the second fin structure;
etching the top structure and the buffer layer, to form a top source region and a top drain region, where a top channel region is provided between the top source region and the top drain region; forming a third spacer on a sidewall of the top structure, etching the bottom structure by using the third spacer as a mask, to form a bottom source region and a bottom drain region, where a bottom channel region is provided between the bottom source region and the bottom drain region;
forming a first bottom source in a bottom source region of the first fin structure, forming a first bottom drain in a bottom drain region of the first fin structure, forming a second bottom source in a bottom source region of the second fin structure, and forming a second bottom drain in a bottom drain region of the second fin structure;
forming a ground connection layer on the first bottom source, forming a first storage bottom electrode on the first bottom drain and the second bottom source, forming a power connection layer on the second bottom drain, where the buried power connection layer is electrically connected to the power connection layer, the buried ground connection layer is electrically connected to the ground connection layer, and the first storage bottom electrode is electrically connected to the first bottom drain and the second bottom source;
forming a first top source and a first top drain on the ground connection layer and the first storage bottom electrode of the first fin structure, and forming a second top source and a second top drain on the power connection layer and the first storage bottom electrode of the second fin structure;
removing the first semiconductor layer in the top channel region and the bottom channel region, to form multiple to-be-filled gaps between the second semiconductor layers;
forming a first-type work function layer in the to-be-filled gaps of the first fin structure, and forming a second-type work function layer in the to-be-filled gaps of the second fin structure; filling the multiple to-be-filled gaps with a gate, where the gate surrounds the second semiconductor layers, a top channel structure and a bottom channel structure are respectively formed by a stack of multiple second semiconductor layers; and
forming a first storage top electrode on the first top drain, where the first storage top electrode is electrically connected to the first storage bottom electrode; forming a top power connection layer on the second top source, and forming a second storage top electrode on the second top drain.

In an embodiment, the forming a first bottom source in a bottom source region of the first fin structure, forming a first bottom drain in a bottom drain region of the first fin structure, forming a second bottom source in a bottom source region of the second fin structure, and forming a second bottom drain in a bottom drain region of the second fin structure, includes:
forming a first epitaxial barrier layer on the second fin structure, forming the first bottom source in the bottom source region of the first fin structure, and forming the first bottom drain in the bottom drain region of the first fin structure;
removing the first epitaxial barrier layer, forming a second epitaxial barrier layer on the first fin structure, forming the second bottom source in the bottom source region of the second fin structure, and forming the second bottom drain in the bottom drain region of the second fin structure; and
removing the second epitaxial barrier layer.

In an embodiment, before the forming a ground connection layer on the first bottom source, forming a first storage bottom electrode on the first bottom drain and the second bottom source, forming a power connection layer on the second bottom drain, the method further includes:
forming a first dielectric layer, where the first dielectric layer overlays the top structure; and
etching the first dielectric layer at both sides of the top structure to form a first groove, where the first bottom source, the first bottom drain, the second bottom source, and the second bottom drain are exposed by the first groove.

The forming a ground connection layer on the first bottom source, forming a first storage bottom electrode on the first bottom drain and the second bottom source, forming a power connection layer on the second bottom drain, includes:
forming the ground connection layer, on the first bottom source exposed by the first groove; forming the first storage bottom electrode, on the first bottom drain and the second bottom source that are exposed by the first groove; and forming the power connection layer, on the second bottom drain exposed by the first groove.

The method further includes:
forming a second dielectric layer in the first groove; and
etching the first dielectric layer and the second dielectric layer, such that surfaces of the first dielectric layer and the second dielectric layer that are opposite to the substrate are flush with a surface of the buffer layer opposite to the substrate.

The forming a first top source and a first top drain on the ground connection layer and the first storage bottom electrode of the first fin structure, and forming a second top source and a second top drain on the power connection layer and the first storage bottom electrode of the second fin structure, includes:
forming the first top source and the first top drain on the first dielectric layer and the second dielectric layer of the first fin structure, forming the second top source and the second top drain on the first dielectric layer and the second dielectric layer of the second fin structure, where the first dielectric layer and the second dielectric layer overlay the ground connection layer and the first storage bottom electrode of the first fin structure, and overlay the power connection layer and the first storage bottom electrode of the second fin structure.

In an embodiment, the forming a first-type work function layer in the to-be-filled gaps of the first fin structure, and forming a second-type work function layer in the to-be-filled gaps of the second fin structure, includes:
forming the second-type work function layer in the to-be-filled gaps of the first fin structure and the to-be-filled gaps of the second fin structure;
forming a first isolation protective layer on the second fin structure, and removing the second-type work function layer in the to-be-filled gap of the first fin structure;
forming the first-type work function layer in the to-be-filled gap of the first fin structure; and
removing the first isolation protective layer.

In an embodiment, before the forming a first storage top electrode on the first top drain, where the first storage top electrode is electrically connected to the first storage bottom electrode; forming a top power connection layer on the second top source, and forming a second storage top electrode on the second top drain, the method further includes:
forming a third dielectric layer, on the first top source, the first top drain, the second top source, and the second top drain; and
etching the third dielectric layer, to form a second groove, where the first top drain, the second top drain, and the second top source are exposed by the second groove.

The forming a first storage top electrode on the first top drain, where the first storage top electrode is electrically connected to the first storage bottom electrode; forming a top power connection layer on the second top source, and forming a second storage top electrode on the second top drain, includes:
forming the first storage top electrode, on the first top drain exposed by the second groove; forming the top power connection layer, on the second top source exposed by the second groove; and forming the second storage top electrode on the second top drain exposed by the second groove.

In an embodiment, before etching the top structure and the buffer layer, the method further includes:
forming a dummy gate and a second spacer, where the second spacer is located at both sides of the dummy gate.

The etching the top structure and the buffer layer, to form a top source region and a top drain region, includes:
etching the top structure and the buffer layer by using the dummy gate and the second spacer as a mask, to form the top source region and the top drain region.

A complementary field-effect transistor is provided according to an embodiment of the present disclosure. The complementary field-effect transistor includes:
a substrate;
a first top source, a first top drain, a first top channel structure, a second top source, a second top drain, a second top channel structure, a first bottom source, a first bottom drain, a first bottom channel structure, a second bottom source, a second bottom drain, and a second bottom channel structure which are provided on a side of the substrate; where a first-type work function layer is provided on surfaces of multiple nanosheets included in the first top channel structure and the first bottom channel structure, a second-type work function layer is provided on surfaces of multiple nanosheets included in the second top channel structure and the second bottom channel structure; and
a gate surrounding the multiple nanosheets.

A ground connection layer is provided on the first bottom source. A first storage bottom electrode is provided on the first bottom drain and the second bottom source. A power connection layer is provided on the second bottom drain. A buried power connection layer is electrically connected to the power connection layer, and a buried ground connection layer is electrically connected to the ground connection layer. The first storage bottom electrode is electrically connected to the first bottom drain and the second bottom source. A first storage top electrode is provided on the first top drain, and the first storage top electrode is electrically connected to the first storage bottom electrode. A top power connection layer is provided on the second top source, and a second storage top electrode is provided on the second top drain.

In an embodiment, the first-type work function layer is an N-type work function layer, and the second-type work function layer is a P-type work function layer.

In an embodiment, materials of the first top source and the first bottom source at least include Si, Si:C, or Si:P, and materials of the first top drain and the first bottom drain at least include SiGe, Si:B, or Ge.

A static random-access memory is provided according to the present disclosure. The static random-access memory includes multiple storage units, and each of the multiple storage units includes the complementary field-effect transistor according to any one of the above embodiments.

An SRAM unit is provided according to the present disclosure. The SRAM unit includes a first complementary field effect transistor (CFET), a second CFET and a third CFET. The first CFET, the second CFET and the third CFET are arranged in parallel, and have parallel channel directions. The second CFET is provided between the first CFET and the third CFET. Upper transistors and lower transistors of both the first CFET and the third CFET are N-type transistors, and an upper transistor and a lower transistor of the second CFET are P-type transistors. The upper transistor of the first CFET and the lower transistor of the third CFET serve as gate transistors. That is, the function of the SRAM unit can be implemented by providing three CFETs arranged in parallel and having parallel channel directions and the upper transistor and the lower transistor in the same conductivity type. By arranging the three CFETs in parallel, the area of the SRAM unit is greatly reduced. In this way, by adjusting the layout structure and providing laterally complementary CFETs according to the present disclosure, the area of the storage unit in the static random-access memory can be reduced compared with the storage unit including vertically complementary CFETs.

### BRIEF DESCRIPTION OF THE DRAWINGS

To clearly illustrate technical solutions in embodiments of the present disclosure, drawings referred to describe the embodiments are briefly described hereinafter. Apparently, the drawings in the following description are only some embodiments of the present disclosure, and for those skilled in the art, other drawings may be acquired based on these drawings without any creative effort.

FIG. 1 is a schematic circuit diagram of a storage unit in a static random-access memory;

FIG. 2 is a schematic diagram illustrating a structure of a storage unit in a static random-access memory;

FIG. 3 is a schematic diagram illustrating another structure of a storage unit in a static random-access memory;

FIG. 4 is a flowchart illustrating a method for manufacturing a complementary field-effect transistor according to an embodiment of the present disclosure;

FIG. 5 is a schematic diagram illustrating a structure of a storage unit in a static random-access memory according to an embodiment of the present disclosure;

FIG. 6 is a schematic diagram illustrating a top tier of the structure provided in FIG. 5;

FIG. 7 is a schematic diagram illustrating a bottom tier of the structure provided in FIG. 5;

FIG. 8 is a schematic perspective structural diagram illustrating a complementary field-effect transistor according to an embodiment of the present disclosure;

FIGS. 9 to 67 are schematic structural diagrams illustrating a complementary field-effect transistor manufactured using a method for manufacturing the complementary field effect transistor according to an embodiment of the present disclosure;

FIG. 68 is a schematic diagram illustrating a structure of a storage unit in a static random-access memory according to an embodiment of the present disclosure; and

FIG. 69 is a flowchart illustrating a method for manufacturing an SRAM according to an embodiment of the present disclosure.

### DETAILED DESCRIPTION

To enable those skilled in the art to better understand the solutions according to the present disclosure, technical solutions in embodiments of the present disclosure are clearly and completely described hereinafter in conjunction with the drawings in the embodiments of the present disclosure. Apparently, the embodiments described are only some embodiments of the present disclosure, rather than all embodiments. Based on the embodiments of the present disclosure, all other embodiments obtained by those skilled in the art without any creative effort fall within the protection scope of the present disclosure.

Various specific details are set forth in following description to facilitate a full understanding of the present disclosure. The present disclosure may be implemented in a manner different from those described herein, and those skilled in the art may perform analogous promotion without departing from concepts of the present disclosure. Therefore, the present disclosure is not limited by the embodiments disclosed hereinafter.

The present disclosure is described in detail in conjunction with schematic diagrams. To facilitate description in describing embodiments of the present disclosure in detail, a cross-sectional view showing a structure of a device is partially enlarged, not on a general scale. The schematic diagrams are merely exemplary, which are not intended to limit the protection scope of present disclosure. In addition, three-dimensional spatial dimensions of length, width, and depth shall be configured in practice.

Reference is made to FIG. 1, which is a schematic circuit diagram of a storage unit in a static random-access memory. A storage unit of SRAM is referred to as a bit, which can only store a single signal, either 0 or 1. Such one bit includes 6 transistors, which includes two P metal-oxide-semiconductor field-effect transistors (PMOS) and four N metal-oxide-semiconductor field-effect transistors (NMOS). In FIG. 1, PU1 and PU2 are PMOS, and PD1, PD2, AC1 and AC2 are NMOS. Q and QB represent storage bits. In FIG. 1, VDD represents a power supply terminal, VSS represents a ground terminal, WL represents a word line, and BL represents a bit line.

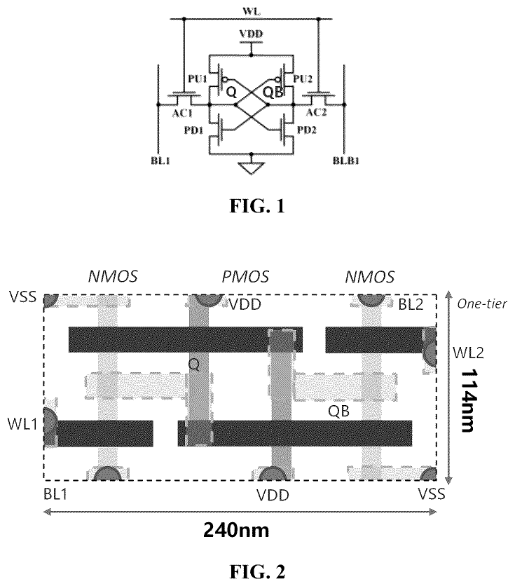

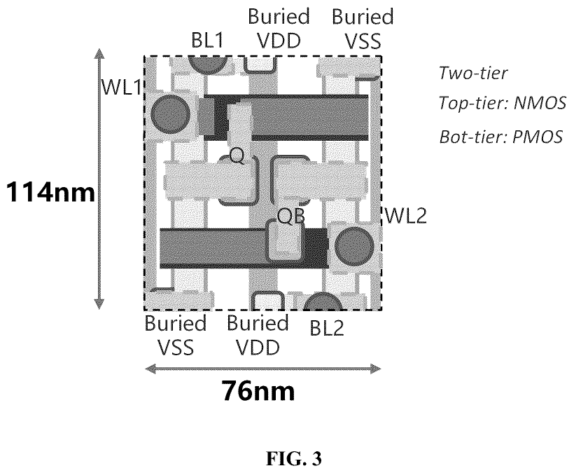

Reference is made to FIGS. 2 and 3, which are schematic diagrams illustrating two structures of a storage unit in a static random-access memory. FIG. 2 shows planar transistors in one-tier structure (One-tier). FIG. 3 shows complementary field-effect transistors in a two-tier structure (Two-tier), with NMOS in a top tier (Top-tier: NMOS) and PMOS in a bottom tier (Bot-tier: PMOS). That is, in the conventional technology, by changing the design of the storage unit from the planar transistors to the complementary field-effect transistors, the length of the storage unit is shortened from 240 nm to 76 nm, and the area of the storage unit in the static random-access memory is greatly reduced.

However, a requirement for a smaller area of the storage unit in the static random-access memory still exists.

Based on this, an SRAM unit is provided according to the present disclosure. The SRAM unit includes a first complementary field-effect transistor (CFET), a second CFET and a third CFET. The first CFET, the second CFET and the third CFET are arranged in parallel, and have parallel channel directions. The second CFET is provided between the first CFET and the third CFET. Upper transistors and lower transistors of both the first CFET and the third CFET are N-type transistors, and an upper transistor and a lower transistor of the second CFET are P-type transistors. The upper transistor of the first CFET and the lower transistor of the third CFET serve as gate transistors. That is, the function of the SRAM unit can be implemented by providing three CFETs arranged in parallel and having parallel channel directions and the upper transistor and the lower transistor in the same conductivity type. By arranging the three CFETs in parallel, the area of the SRAM unit is greatly reduced. In this way, by adjusting the layout structure and providing laterally complementary CFETs according to the present disclosure, the area of a storage unit in the static random-access memory can be reduced compared with the storage unit including vertically complementary CFETs.

To facilitate understanding technical solutions and technical effects of the present disclosure, hereinafter embodiments are described in detail in conjunction with the drawings.

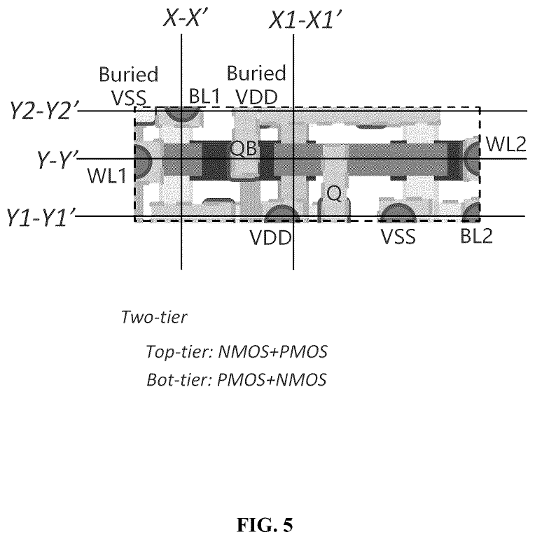

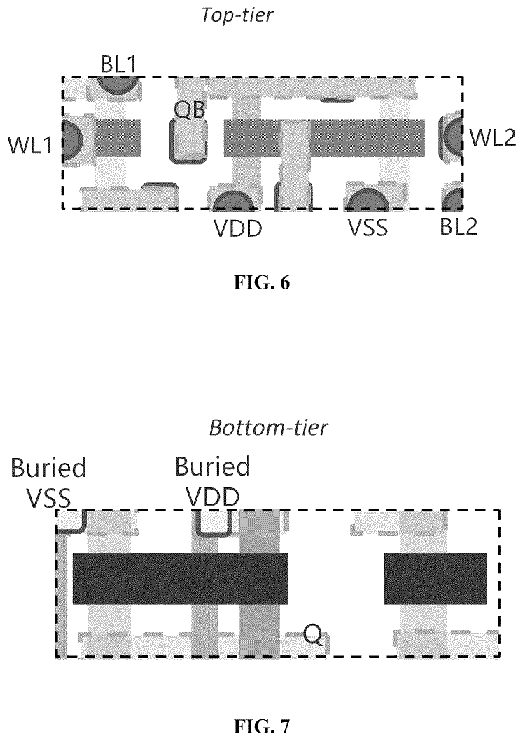

Reference is made to FIG. 5, which is a schematic diagram illustrating a structure of a storage unit in a static random-access memory according to an embodiment of the present disclosure. The structure of the storage unit in FIG. 5 includes two tiers. A top tier is shown with reference to FIG. 6, and a bottom tier is shown with reference to FIG. 7.

The static random-access memory (SRAM) unit according to an embodiment of the present disclosure includes three complementary field-effect transistors (CFET), which are a first CFET, a second CFET, and a third CFET, respectively.

The first CFET, the second CFET, and the third CFET are arranged in parallel, and have parallel channel directions. The channel direction may be perpendicular to the arrangement direction. The second CFET is provided between the first CFET and the third CFET. Referring to FIG. 5, the first CFET, the second CFET, and the third CFET are arranged in parallel along a Y-Y′ direction, and channel directions of the first CFET, the second CFET, and the third CFET are in an X-X′ direction.

Each CFET includes two transistors stacked vertically. An upper transistor and a lower transistor of each CFET have the same conductivity type. Upper transistors and lower transistors of both the first CFET and the third CFET are N-type transistors, and an upper transistor and a lower transistor of the second CFET are P-type transistors. The upper transistor of the first CFET and the lower transistor of the third CFET serve as gate transistors.

That is, by configuring each CFET with the upper transistor and the lower transistor in the same conductivity type, PMOS and NMOS can be separated completely, thereby preventing sticking of the NMOS and the PMOS, as compared with configuring each CFET with the upper transistor and the lower transistor in different conductivity types. According to the present disclosure, by adjusting the layout structure and providing laterally complementary CFETs, the process difficulty can be reduced compared with providing different types of transistors stacked vertically, thereby improving process controllability. Compared with the vertical arrangement of complementary CFETs, the area of the SRAM unit can be reduced from 114 nm×76 nm to 130 nm×57 nm, as shown in FIG. 68. The specific value of the area reduction of the storage unit shown in FIG. 68 is merely an example, and the actual extent of the area reduction in the present disclosure is not limited herein.

In an embodiment of the present disclosure, the first CFET includes: a first top source 135, a first top drain 136, a first top channel structure, a first bottom source 131, a first bottom drain 132, and a first bottom channel structure. The first top source 135 and the first top drain 136 are respectively located at two sides of the first top channel structure. The first bottom source 131 and the first bottom drain 132 are respectively located at two sides of the first bottom channel structure. The second CFET includes: a second top source 137, a second top drain 138, a second top channel structure, a second bottom source 133, a second bottom drain 134, and a second bottom channel structure. The second top source 137 and the second top drain 138 are respectively located at two sides of the second top channel structure. The second bottom source 133 and the second bottom drain 134 are respectively located at two sides of the second bottom channel structure. The third CFET includes: a third top source, a third top drain, a third top channel structure, a third bottom source, a third bottom drain, and a third bottom channel structure. The third top source and the third top drain are respectively located at two sides of the third top channel structure. The third bottom source and the third bottom drain are respectively located at two sides of the third bottom channel structure.

The SRAM unit includes multiple gates 160. The multiple gates 160 respectively surround a nanosheet included in the first top channel structure, a nanosheet included in the first bottom channel structure, a nanosheet included in the second top channel structure, a nanosheet included in the second bottom channel structure, a nanosheet included in the third bottom channel structure, and a nanosheet included in the third bottom channel structure. The nanosheet is a channel. The nanosheet included in the first top channel structure, the nanosheet included in the first bottom channel structure, the nanosheet included in the second top channel structure, the nanosheet included in the second bottom channel structure, the nanosheet included in the third top channel structure, and the nanosheet included in the third bottom channel structure may be respectively surrounded by different gates 160, to form different transistors.

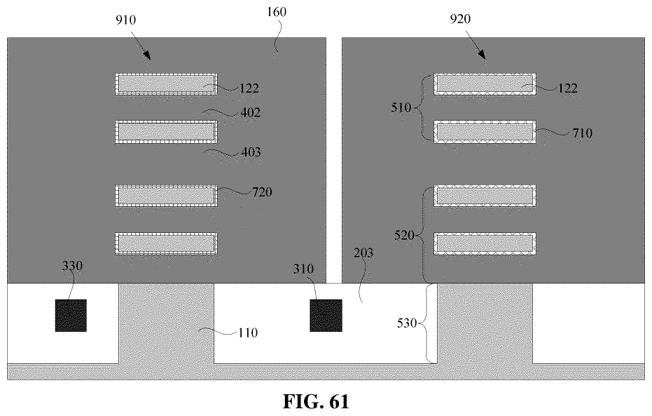

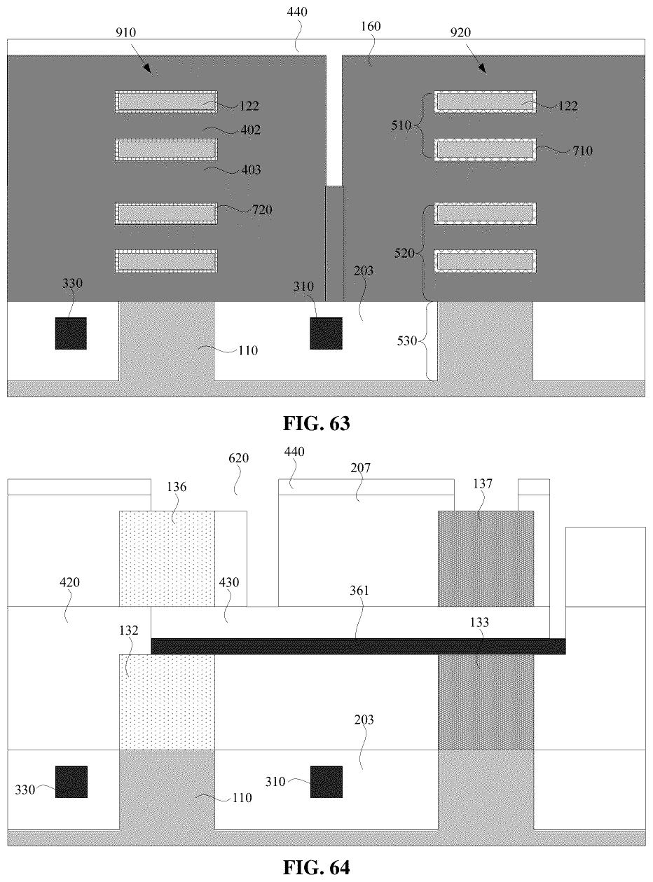

Referring to FIGS. 61 and 63, structures of the first CFET and the second CFET are shown. The upper transistor and the lower transistor of the first CFET may be surrounded by one gate 160, and the upper transistor and the lower transistor of the second CFET may be surrounded by another gate 160.

In an embodiment, the gates 160 include top gates that respectively surround the nanosheets included in the top channel structures for the respective CFETs and bottom gates that surround the nanosheets included in the bottom channel structures for the respective CFETs. The bottom gates of the first CFET and the second CFET are connected with each other. The top gates of the second CFET and the third CFET are connected with each other. Referring to FIGS. 6 and 7, the bottom gates of the first CFET and the second CFET are connected with each other, to electrically connect the N-type lower transistor in the first CFET with the P-type lower transistor in the second CFET. The top gates of the second CFET and the third CFET are connected with each other, to electrically connect the P-type upper transistor in the second CFET with the N-type upper transistor in the third CFET. In this way, the transistors arranged in parallel for different CFETs are connected with each other to form laterally complementary transistors.

In an embodiment of the present disclosure, a first-type work function layer 720 is provided on surfaces of multiple nanosheets included in the first top channel structure and the first bottom channel structure. A second-type work function layer 710 is provided on surfaces of multiple nanosheets included in the second top channel structure and the second bottom channel structure. The first-type work function layer 720 is provided on surfaces of multiple nanosheets included in the third top channel structure and the third bottom channel structure. That is, by providing the upper transistor and the lower transistor of the first CFET with the same type of work function layer, the upper transistor and the lower transistor of the first CFET in the same conductivity type can be implemented. Accordingly, by providing the upper transistor and the lower transistor of the second CFET with the same type of work function layer, the upper transistor and the lower transistor of the second CFET in the same conductivity type can be implemented. By providing the upper transistor and the lower transistor of the third CFET with the same type of work function layer, the upper transistor and the lower transistor of the third CFET in the same conductivity type can be implemented. By providing the first CFET and the second CFET with different types of work function layers, the conductivity type of the first CFET can be different from that of the second CFET. By providing the first CFET and the third CFET with the same type of work function layer, the conductivity type of the first CFET can be the same as that of the third CFET.

In an embodiment, the first-type work function layer 720 is an N-type work function layer, and the second-type work function layer 710 is a P-type work function layer. That is, the first CFET has an N-type work function layer, and thus the upper transistor and the lower transistor of the first CFET are N-type transistors. The second CFET has a P-type work function layer, and thus the upper transistor and the lower transistor of the second CFET are P-type transistors. The third CFET has an N-type work function layer, and thus the upper transistor and the lower transistor of the third CFET are N-type transistors.

In an embodiment of the present disclosure, a first storage bottom electrode 361 is provided on the first bottom drain 132, and the first storage bottom electrode 361 is electrically connected to the first bottom drain 132 and the second bottom source 133. A ground connection layer 331 is provided on the first bottom source 131. A buried power connection layer 310 is provided in a substrate 110 of the first CFET. The buried power connection layer 310 is provided between the first CFET and the second CFET. A power connection layer 320 is provided on the second bottom drain 134. The buried power connection layer 310 is electrically connected to the power connection layer 320. A buried ground connection layer 330 is electrically connected to the ground connection layer 331. As can be seen from FIG. 7, a buried power connection layer (Buried VDD) and a buried ground connection layer (Buried VSS) can be provided to achieve power connection and ground connection of the complementary field effect transistor.

In an embodiment of the present disclosure, a first storage top electrode 362 is provided on the first top drain 136, and the first storage top electrode 362 is electrically connected to the first storage bottom electrode 361. The first storage top electrode 362 is connected to the first top drain 136 of the first CFET, and is also connected to a top gate of the second CFET and a top gate of the third CFET.

In an embodiment of the present disclosure, a top power connection layer 321 is provided on the second top source 137, and a second storage top electrode 372 is provided on the second top drain 138. The second storage top electrode 372 is connected to the third bottom source of the third CFET, a bottom gate of the first CFET, a bottom gate of the second CFET, the second top drain 138 of the second CFET, and the third top drain of the third CFET.

Q bit in the SRAM unit is implemented by providing the first storage top electrode 362 and the first storage bottom electrode 361, and QB bit in the SRAM unit is implemented by providing the second storage top electrode 372.

In the SRAM unit according to the present disclosure, the same work function layer is simultaneously formed on transistors stacked vertically in one CFET, and then horizontal transistors of different CFETs are connected with each other through planar interconnection and vertical vias, to form lateral complementary transistors. According to the present disclosure, compared with a delamination process of forming vertically stacked transistors having different types of work function layers, a highly controllable partition process can be achieved through a simple lateral partition process for horizontal work function layers, and PMOS and NMOS can be separated completely, thereby preventing sticking of the NMOS and the PMOS. The lateral complementary transistors according to the present disclosure have vertically asymmetric buried VDD or asymmetric buried VSS, and also have an asymmetric word line lead-out structure and an asymmetric bit line lead-out structure.

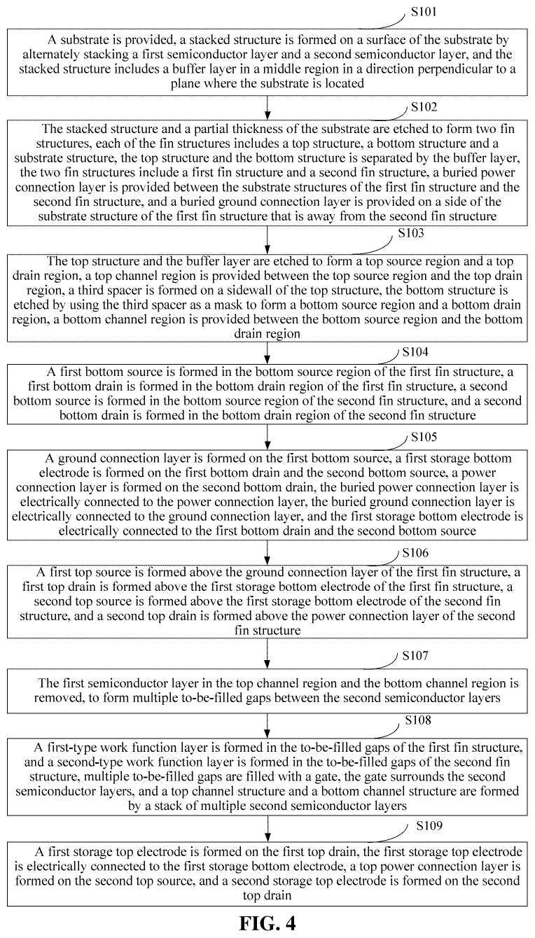

Reference is made to FIG. 4, which is a flowchart illustrating a method for manufacturing a complementary field-effect transistor according to an embodiment of the present disclosure.

In the embodiment of the present disclosure, the complementary field-effect transistor is manufactured according to the structure layout of the storage unit in the static random-access memory shown in FIG. 5.

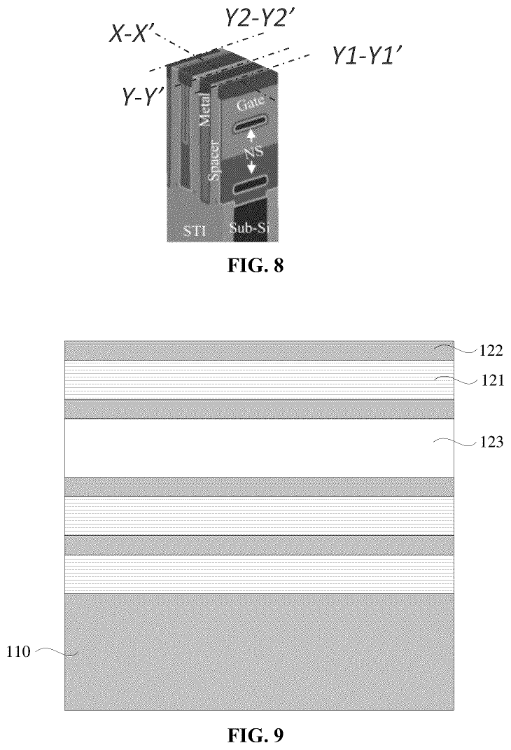

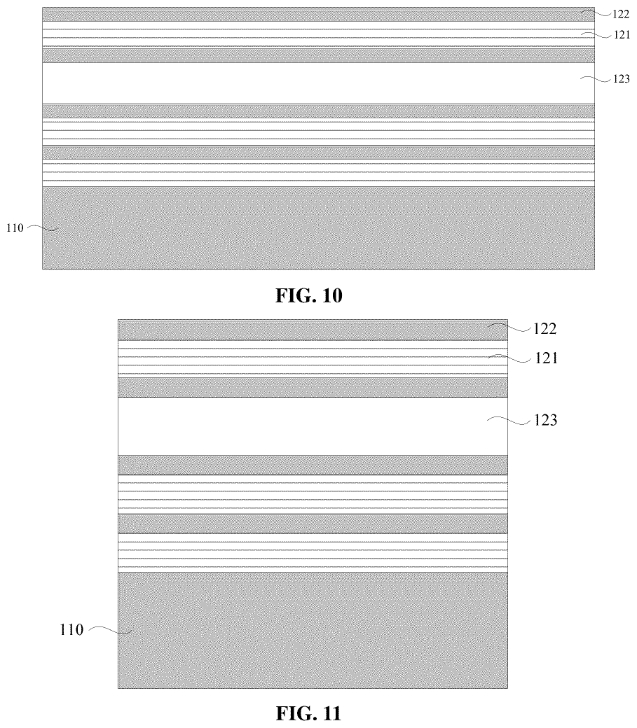

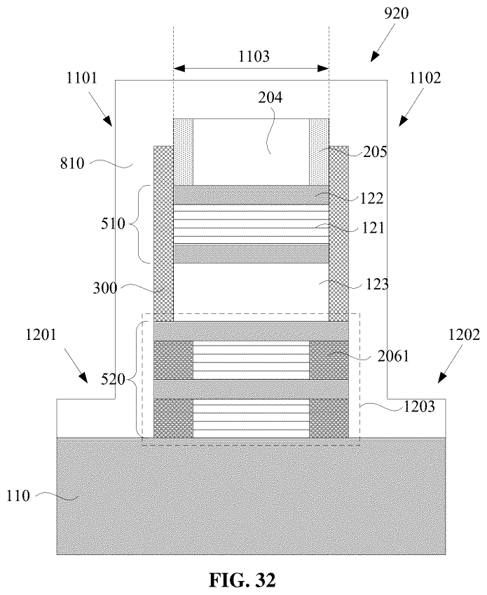

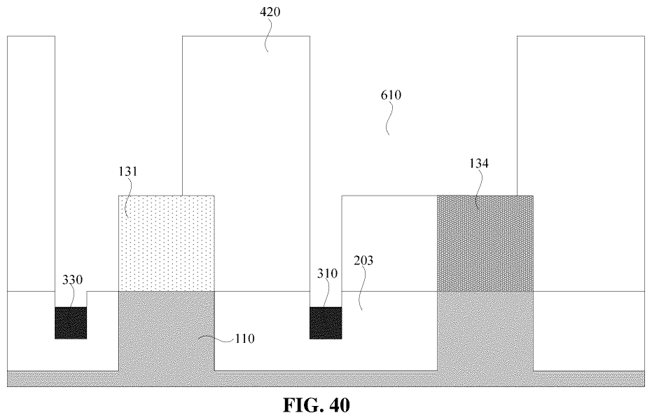

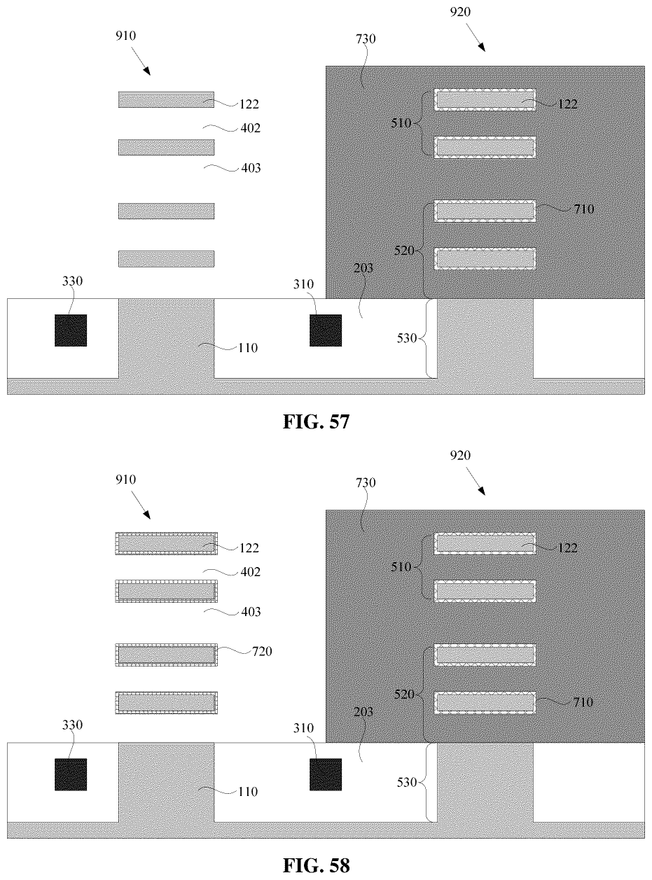

FIG. 8 is a schematic perspective structural view illustrating a complementary field-effect transistor according to an embodiment of the present disclosure. Multiple cross-sectional structural views of the complementary field-effect transistor are obtained by taking cross-sections along directions of X-X′, Y-Y′, X1-X1′, Y1-Y1′, and Y2-Y2′ on the schematic perspective structural view, respectively. FIGS. 9, 11, 13, 15, 17, 19, 21, 23, 25, 27, 28, 29, 30, 31, 33, 35, 37, 39, 41, 43, 45, 48, 49, 50, 52, 54, 56, 58, 60, and 62 are schematic cross-sectional structural views along the X-X′ direction. FIGS. 10, 12, 14, 16, 18, 20, 22, 24, 26, 38, 51, 53, 55, 57, 59, 61, and 63 are schematic cross-sectional structural views along the Y-Y′ direction. FIGS. 32, 34, and 36 are schematic cross-sectional structural views along the X1-X1′ direction. FIGS. 46, 64, and 66 are schematic cross-sectional structural views along the Y1-Y1′ direction. FIGS. 40, 42, 44, 47, 65, and 67 are schematic cross-sectional structural views along the Y2-Y2′ direction.

The method for manufacturing the complementary field-effect transistor according to an embodiment of the present disclosure includes the following steps.

In step S101, a substrate is provided, a stacked structure is formed on a surface of the substrate by alternately stacking a first semiconductor layer and a second semiconductor layer, and the stacked structure includes a buffer layer in a middle region in a direction perpendicular to a plane where the substrate is located, referring to FIGS. 9 and 10.

In an embodiment of the present disclosure, a substrate 110 may be a semiconductor substrate, such as a bulk silicon substrate. The substrate 110 may be doped to obtain a P-type semiconductor substrate or an N-type semiconductor substrate, such as a P-type silicon substrate or an N-type silicon substrate.

As an example, a highly-doped well region may be formed by implanting impurities into a bulk silicon substrate and performing annealing, to achieve a desired well depth. For different device types, the doping type of the substrate 110 varies. For the p-type semiconductor device, the highly-doped well region is N-well, and the implanted impurities are n-type impurity ions, such as phosphorus (p) ions. For the N-type semiconductor device, the highly-doped well region is p-well, and the implanted impurities are p-type impurity ions, such as boron (B) ions.

In an embodiment of the present disclosure, a stacked structure is formed on a surface of the substrate 110 by alternately stacking a first semiconductor layer 121 and a second semiconductor layer 122, referring to FIGS. 9 and 10.

In an embodiment, for different device types, materials of the first semiconductor layer 121 and the second semiconductor layer 122 may be the same. For example, the material of the first semiconductor layer 121 may be silicon germanium, and the material of the second semiconductor layer 122 may be silicon or germanium. For different device types, the materials of the first semiconductor layer 121 and the second semiconductor layer 122 may be different. For example, for a P-type semiconductor device, the material of the first semiconductor layer 121 may be silicon, and the material of the second semiconductor layer 122 may be silicon germanium. For an N-type semiconductor device, the material of the first semiconductor layer 121 may be silicon germanium, and the material of the second semiconductor layer 122 may be silicon.

In the direction perpendicular to the plane where the substrate 110 is located, the stacked structure includes a buffer layer 123 in the middle region. The buffer layer 123 is configured to separate two transistors stacked vertically that are formed subsequently. The material of the buffer layer 123 may be the same as that of the first semiconductor layer 121, and the thickness of the buffer layer 123 may be larger than that of the first semiconductor layer 121. The second semiconductor layer 122 is provided on both sides of the buffer layer 123.

In practice, silicon oxide may be formed on the substrate 110. The stacked structure may be formed after the silicon oxide is removed on the substrate 110 and the substrate 110 is cleaned.

In step S102, the stacked structure and a partial thickness of the substrate are etched to form two fin structures, each of the two fin structures includes a top structure, a bottom structure, and a substrate structure, the top structure and the bottom structure is separated by the buffer layer, the two fin structures include a first fin structure and a second fin structure, a buried power connection layer is provided between the substrate structure of the first fin structure and the substrate structure of the second fin structure, and a buried ground connection layer is provided on a side of the substrate structure of the first fin structure that is away from the second fin structure, referring to FIGS. 11 to 24.

In an embodiment of the present disclosure, the stacked structure and a partial thickness of the substrate 110 may be etched to form two fin structures, which are a first fin structure 910 and a second fin structure 920, respectively. Each fin structure includes a top structure 510, a bottom structure 520, and a substrate structure 530. The top structure 510 and the bottom structure 520 are separated by a buffer layer 123. After the fin structures are formed, a buried power connection layer 310 may be formed between the substrate structures 530 included in the two fin structures. That is, the buried power connection layer 310 is provided between the substrate structure 530 of the first fin structure 910 and the substrate structure 530 of the second fin structure 920. A buried ground connection layer 330 may be formed when the buried power connection layer 310 is formed. The buried ground connection layer 330 is provided on a side of the substrate structure 530 of the first fin structure 910 that is away from the second fin structure 920. The process flow of forming the fin structures, the buried power connection layer 310 and the buried ground connection layer 330 is described in detail below.

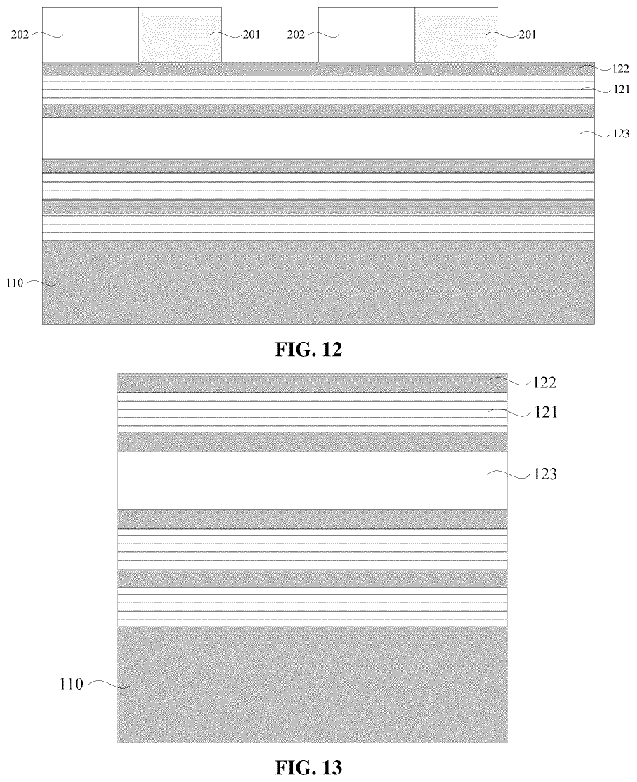

In step S1021, a spacer transfer process is performed, referring to FIGS. 11 and 12.

In an embodiment of the present disclosure, a first spacer 201 is formed through a self-alignment spacer transfer process, and the material of the first spacer 201 is silicon nitride. The specific formation process is as follows: covering the stacked structure with a sacrificial layer 202, where the material of the sacrificial layer 202 may be polysilicon or amorphous silicon; patterning by photolithography to remove a part of the sacrificial layer 202 through etching; depositing a silicon nitride material, and removing the remaining sacrificial layer 202 through anisotropic etching to form the first spacer 201 on the stacked structure. The first spacer 201 serves as a hard mask in the subsequent photolithography process for forming fins.

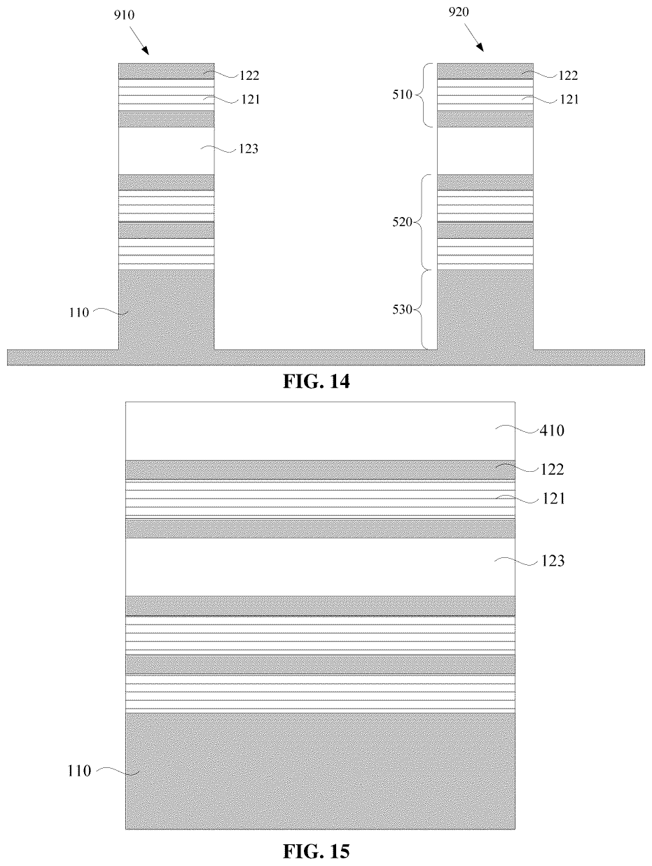

In step S1022, the fin structures are formed, referring to FIGS. 13 and 14.

In an embodiment of the present disclosure, the stacked structure and a partial thickness of the substrate may be etched through an etching process, to form multiple fins arranged at equal spacing, referring to FIGS. 13 and 14. Etching is performed by using the first spacer 201 as a mask, to form the fin with the stacked structure. An upper portion of the fin includes a top structure 510 and a bottom structure 520 that are formed by the stacked structure. The top structure 510 and the bottom structure 520 are separated by the buffer layer 123. The top structure 510 and the bottom structure 520 serve as channel regions. A lower portion of the fin includes the substrate 110. The above structure forms the fin as shown in FIG. 14. The fin includes not only the stacked structure, but also a monocrystalline silicon structure that extends to the substrate 110. The etching process may be dry etching or wet etching. In an embodiment, reactive ion etching may be employed. The fin structure is used to form the nanosheet of the complementary field-effect transistor. Although FIG. 14 shows two fins, it should be understood that any suitable number and configuration of fins can be used in practice.

In practice, the first spacer 201 may be removed after the fin structure is formed.

In step S1023, the buried ground connection layer 330 and the buried power connection layer 310 are formed, referring to FIGS. 15 to 22.

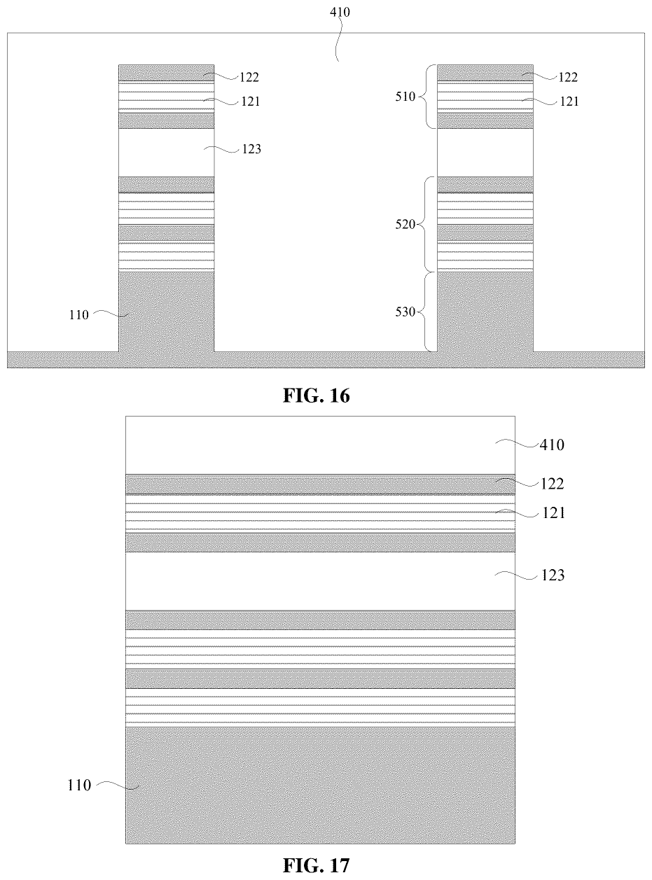

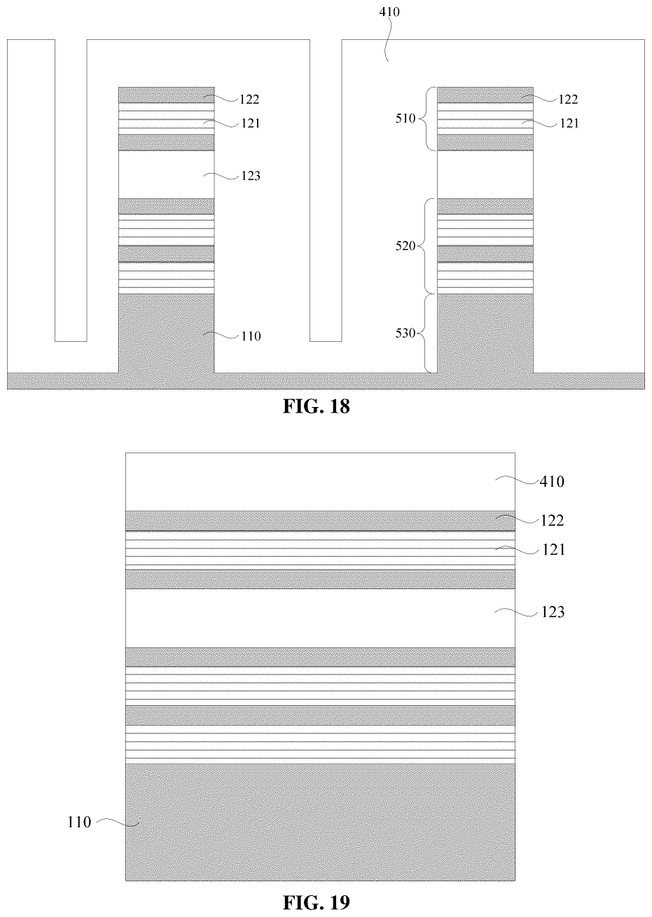

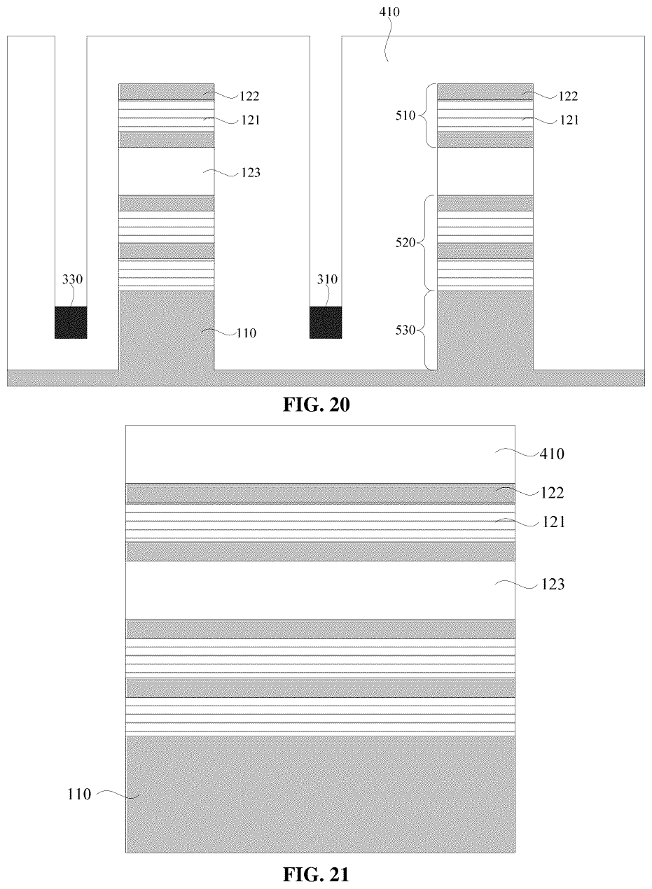

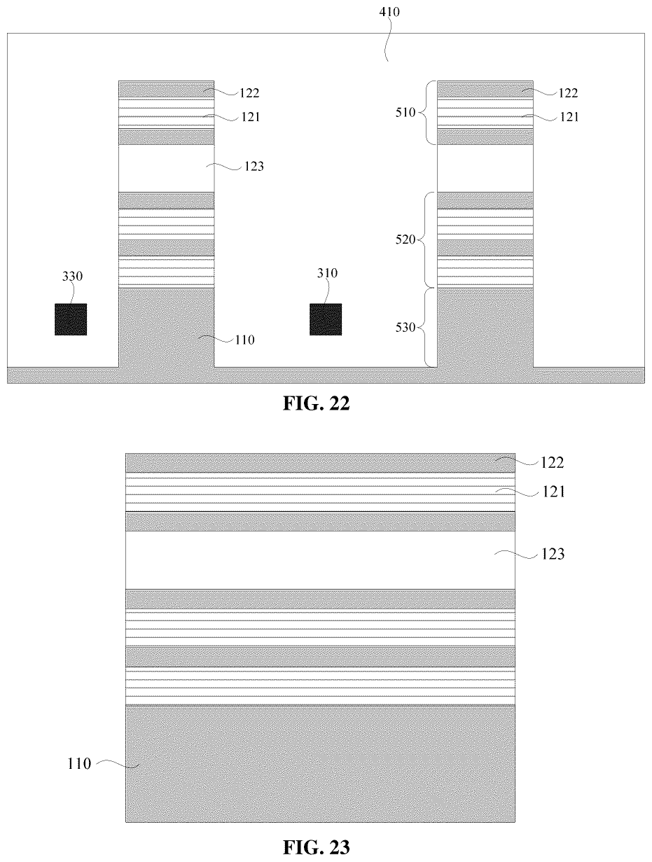

In an embodiment of the present disclosure, the buried power connection layer 310 may be formed between the substrate structure 530 of the first fin structure 910 and the substrate structure 530 of the second fin structure 920. The buried ground connection layer 330 may be formed on a side of the substrate structure 530 of the first fin structure 910 that is away from the second fin structure 920, referring to FIG. 16. Specifically, a dielectric insulating material is deposited, and then planarization such as a CMP process is performed to form an insulating layer 410, referring to FIGS. 15 and 16. The insulating layer 410 on the side of the first fin structure 910 away from the second fin structure 920 and the insulating layer 410 between the first fin structure 910 and the second fin structure 920 are etched such that the depth of the remaining insulating layer 410 is lower than that of the substrate structure 530, to form recesses, referring to FIGS. 17 and 18. The recesses formed through etching are filled with a metal material, such as tungsten (W), and then planarization and etchback are performed, to form the buried ground connection layer 330 and the buried power connection layer 310, referring to FIGS. 19 and 20. Finally, the dielectric insulating material is deposited, and then planarization is performed, to fill the recesses, referring to FIGS. 21 and 22.

In step S1024, shallow trench isolation (STI) 203 is formed, referring to FIGS. 23 and 24.

In an embodiment of the present disclosure, the shallow trench isolation 203 may be formed between the fins. In an embodiment, a selective etchback process is performed on the insulating layer 410 formed in step S1023, to expose the three-dimensional fins. Specifically, the top structures 510 and the bottom structures 520 of the first fin structure 910 and the second fin structure 920 are exposed, to form the shallow trench isolation 203 between adjacent fin structures. A surface of the shallow trench isolation 203 opposite to the substrate 110 may be flush with, or may be higher or lower than, a surface of the stacked structure in the fin structure face to the substrate 110. The shallow trench isolation 203 may be formed of a suitable dielectric material, such as silicon dioxide or silicon nitride. The function of the shallow trench isolation 203 is to separate channels on adjacent fin structures.

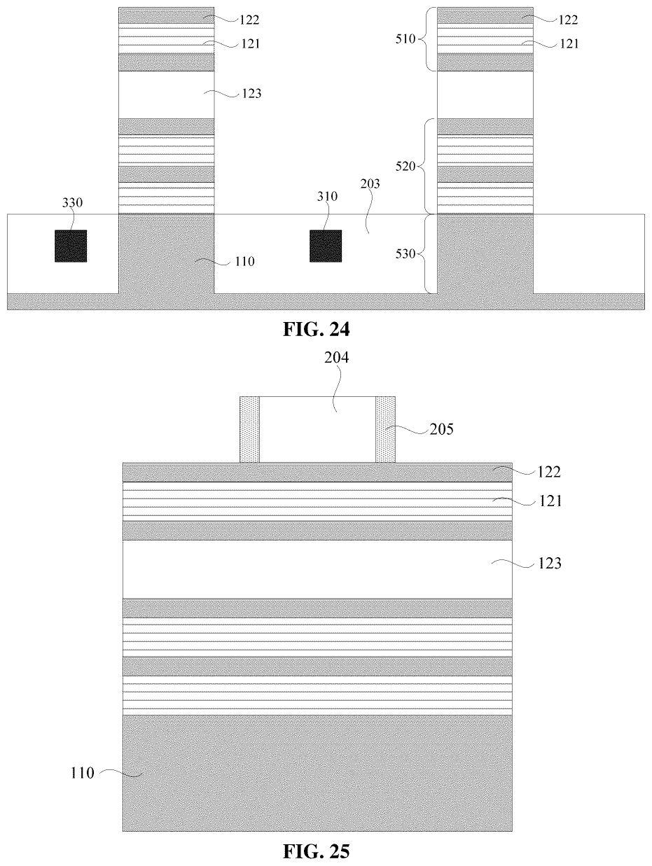

In step S103, the top structure and the buffer layer are etched to form a top source region and a top drain region, a top channel region is provided between the top source region and the top drain region, a third spacer is formed on a sidewall of the top structure, the bottom structure is etched by using the third spacer as a mask to form a bottom source region and a bottom drain region, a bottom channel region is provided between the bottom source region and the bottom drain region, referring to FIGS. 25 to 29.

In an embodiment of the present disclosure, considering the formation of two transistors which are stacked vertically and have the same doping type, the source and the drain of each transistor are to be formed separately. First, a source region and a drain region of the two transistors are to be formed, and the specific process is described in detail below.

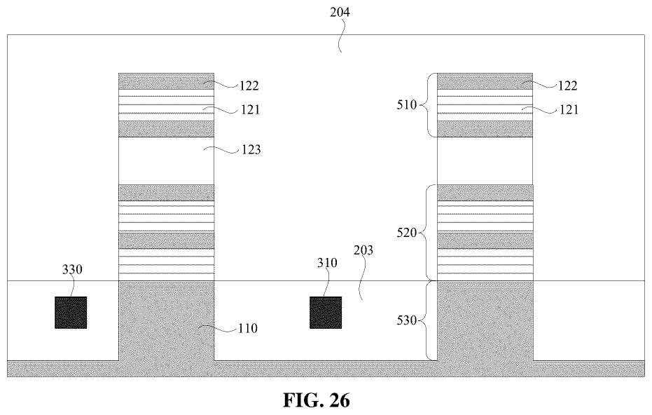

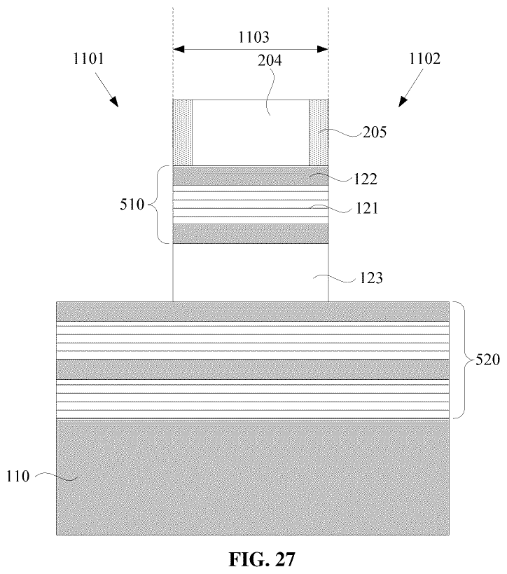

In step S1031, a dummy gate 204 and a second spacer 205 are formed, referring to FIGS. 25 and 26.

In an embodiment of the present disclosure, in a direction perpendicular to a fin line, i.e., an X-X′ direction, a dummy gate stack is formed on the exposed fin structure. The dummy gate stack has a multi-layer structure, including a gate insulating dielectric layer (not shown), the dummy gate 204, and a hard mask layer (not shown). The dummy gate stack may be formed through some processes, such as thermal oxidation, chemical vapor deposition, or sputtering. The dummy gate stack spans the stacked structure at the upper portion of the fin structure, and multiple dummy gates are arranged at equal distances along a direction of the fin line. The material of the dummy gate 204 may be polysilicon or amorphous silicon. The material of the hard mask layer may be an oxide, carbide, an organic matter, or the like.

In an embodiment of the present disclosure, second spacers 205 that have the same thickness may be provided on both sides of the dummy gate stack along the direction of the fin line, i.e., the Y-Y′ direction, respectively. The material of the second spacer 205 may be a dielectric material having isolation properties, such as silicon nitride or doped silicon oxide.

In step S1032, the top structure 510 and the buffer layer 123 are etched, to form a top source region 1101 and a top drain region 1102, referring to FIG. 27.

In an embodiment of the present disclosure, after the dummy gate 204 and the second spacer 205 are formed, source-drain etching is performed on the stacked structure through etching process by using the dummy gate 204 and the second spacer 205 as a mask. Specifically, the source-drain etching is performed on the top structures 510 and the buffer layers 123 of the first fin structure 910 and the second fin structure 920, to form the top source regions 1101 and the top drain regions 1102 of the first fin structure 910 and the second fin structure 920. A top channel region 1103 is provided between the top source region 1101 and the top drain region 1102. The top source region 1101 and the top drain region 1102 no longer include the stacked structure after being formed through etching, referring to FIG. 27.

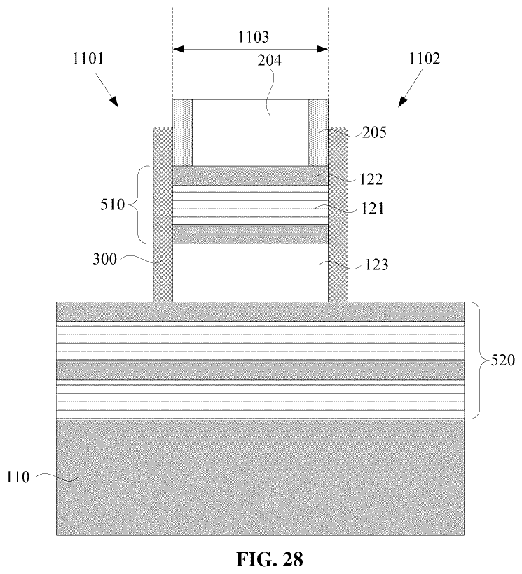

In step S1033, a third spacer 300 is formed on a sidewall of the top structure 510, referring to FIG. 28.

In an embodiment of the present disclosure, after the top structure 510 and the buffer layer 123 are etched to obtain the top source region 1101 and the top drain region 1102, the third spacer 300 may be formed on the sidewall of the top structure 510. That is, third spacers 300 may be provided on both sides of the etched stacked structure along the direction of the fin line, i.e., the Y-Y′ direction, respectively. The third spacers 300 on both sides of the etched stacked structure have the same thickness. The material of the third spacer 300 may be a dielectric material having isolation properties, such as silicon nitride or doped silicon oxide. Referring to FIG. 28, the third spacer 300 also overlays a sidewall of the second spacer 205.

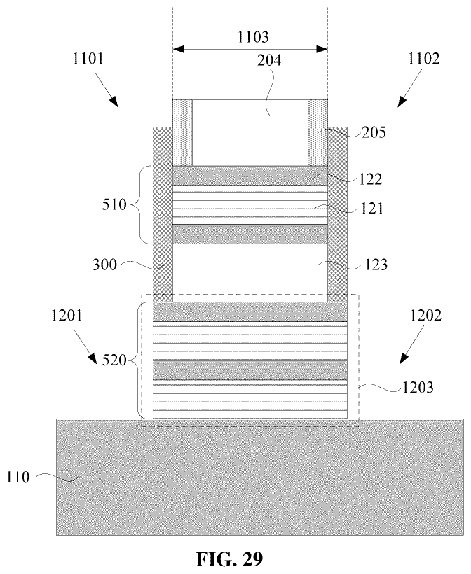

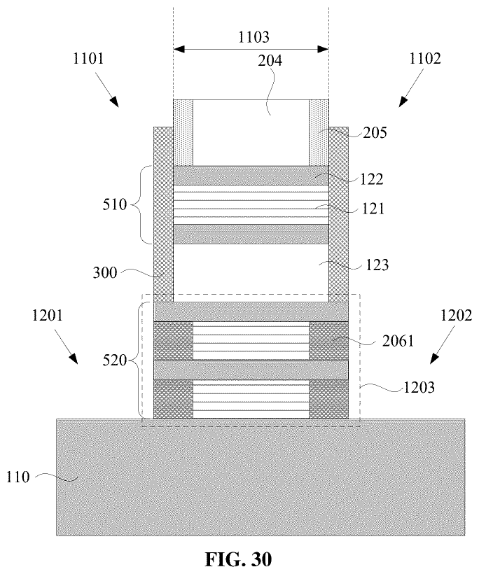

In step S1034, the bottom structure 520 is etched by using the third spacer 300 as a mask, to form a bottom source region 1201 and a bottom drain region 1202, referring to FIG. 29.

In an embodiment of the present disclosure, after the third spacer 300 is formed, source-drain etching is performed on the stacked structure through etching process by using the dummy gate 204, the second spacer 205, and the third spacer 300 as a mask. Specifically, source-drain etching is performed on the bottom structure 520, to form the bottom source region 1201 and the bottom drain region 1202. A bottom channel region 1203 is provided between the bottom source region 1201 and the bottom drain region 1202. The bottom source region 1201 and the bottom drain region 1202 no longer include a stacked structure after being formed through etching, as shown in FIG. 29.

In step S104, a first bottom source is formed in the bottom source region of the first fin structure, a first bottom drain is formed in the bottom drain region of the first fin structure, a second bottom source is formed in the bottom source region of the second fin structure, and a second bottom drain is formed in the bottom drain region of the second fin structure, referring to FIGS. 30 to 36.

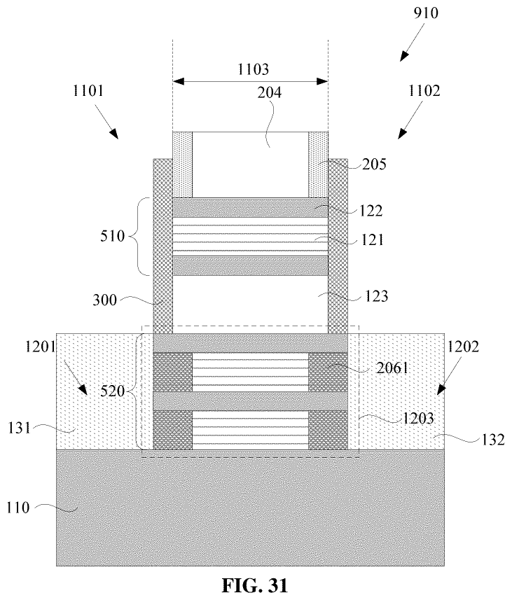

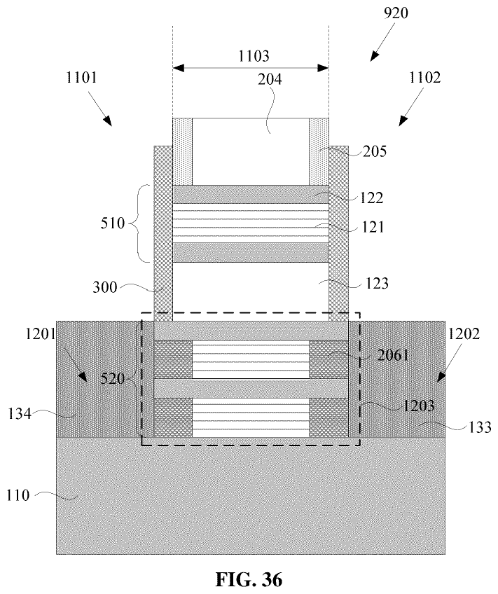

In an embodiment of the present disclosure, after the stacked structure is etched to form the bottom source region 1201 and the bottom drain region 1202, a first bottom source 131 may be formed in the bottom source region 1201 of the first fin structure 910, and a first bottom drain 132 may be formed in the bottom drain region 1202 of the first fin structure 910, referring to FIGS. 31 and 35. A second bottom source 133 is formed in the bottom source region 1201 of the second fin structure 920, and a second bottom drain 134 is formed in the bottom drain region 1202 of the second fin structure 920, as shown in FIGS. 34 and 36. Surfaces of the first bottom source 131, the first bottom drain 132, the second bottom source 133 and the second bottom drain 134 that are opposite to the substrate 110 may be flush with a surface of the buffer layer 123 facing to the substrate 110.

In an embodiment of the present disclosure, before forming the first bottom source 131, the first bottom drain 132, the second bottom source 133 and the second bottom drain 134, a bottom inner spacer may be formed on a sidewall of the fin along the Y-Y′ direction, and the specific process is as follows.

In step S1041, a concave structure is formed.

In an embodiment of the present disclosure, selective etching is performed on the first semiconductor layer 121 in the bottom structure 520 in the Y-Y′ direction. That is, only the first semiconductor layer 121 is etched without damaging the second semiconductor layer 122. Thus, a concave structure is formed of the etched first semiconductor layer 121 and the second semiconductor layer 122 in the Y-Y′ direction. That is, pull-back etching is performed to etch a part of the first semiconductor layer 121 in a direction from the bottom source region 1201 and the bottom drain region 1202 to the bottom channel region 1203.

In step S1042, a bottom inner spacer 2061 is formed, referring to FIG. 30.

In an embodiment of the present disclosure, after the first semiconductor layer 121 is etched, a dielectric material is deposited on the bottom structure 520 in the bottom channel region 1203, that is, on an outer periphery of the fin, and the dielectric material is etched to form the bottom inner spacer 2061. The bottom inner spacer 2061 is flush with the second semiconductor layer 122 in a direction perpendicular to the plane where the substrate 110 is located. That is, the concave structure formed through etching in S1041 is filled up with the bottom inner spacer 2061. The material of the bottom inner spacer 2061 may be silicon nitride or silicon oxide.

In an embodiment, for different types of semiconductor devices, a source-drain material may be varied. For a P-type semiconductor device, the source-drain material is boron-doped silicon germanium, that is, SiGe:B. For an N-type semiconductor device, the source-drain material is carbon-doped silicon, that is, Si:C. Considering the formation of two transistors which are stacked vertically and have the same doping type, the two fin structures are to form transistors that have different doping types subsequently, different source-drain materials are employed to form the source and drain of the first fin structure 910 and the source and drain of the second fin structure 920. The specific process flow of forming the first bottom source 131, the first bottom drain 132, the second bottom source 133, and the second bottom drain 134 is as follows.

In step S1043, a first epitaxial barrier layer 810 is formed on a surface of the second fin structure 920, the first bottom source 131 is formed in the bottom source region 1201 of the first fin structure 910, and the first bottom drain 132 is formed in the bottom drain region 1202 of the first fin structure 910, referring to FIGS. 31 and 32.

In an embodiment of the present disclosure, in the process of forming the first bottom source 131 and the first bottom drain 132, the first epitaxial barrier layer 810 may be formed on the second fin structure 920 to prevent damage to the second fin structure 920, and the first epitaxial barrier layer 810 covers the second fin structure 920, referring to FIG. 32. After the second fin structure 920 is protected from being damaged by the first epitaxial barrier layer 810, the first bottom source 131 may be formed in the bottom source region 1201 of the first fin structure 910, and the first bottom drain 132 may be formed in the bottom drain region 1202 of the first fin structure 910, referring to FIG. 31.

As an example, the material of the first bottom source 131 and the first bottom drain 132 is Si:C.

In step S1044, the first epitaxial barrier layer 810 is removed, a second epitaxial barrier layer 820 is formed on a surface of the first fin structure 910, the second bottom source 133 is formed in the bottom source region 1201 of the second fin structure 920, and the second bottom drain 134 is formed in the bottom drain region 1202 of the second fin structure 920.

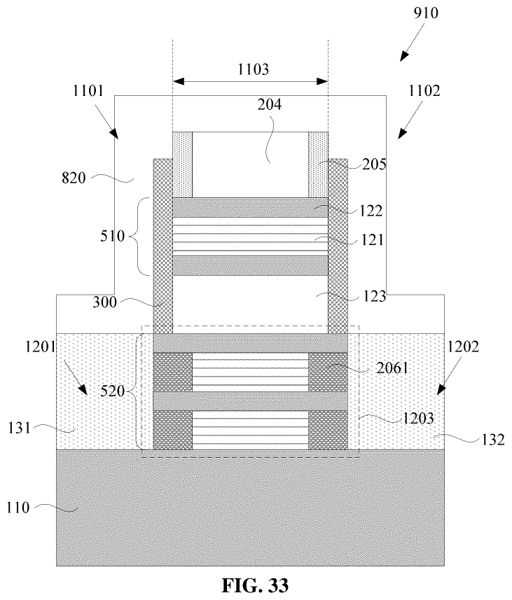

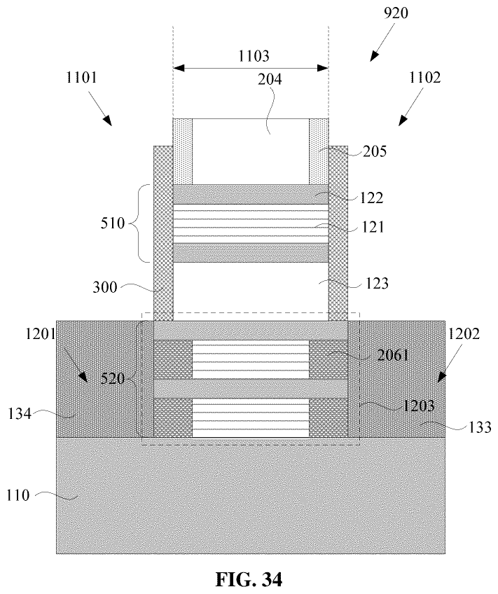

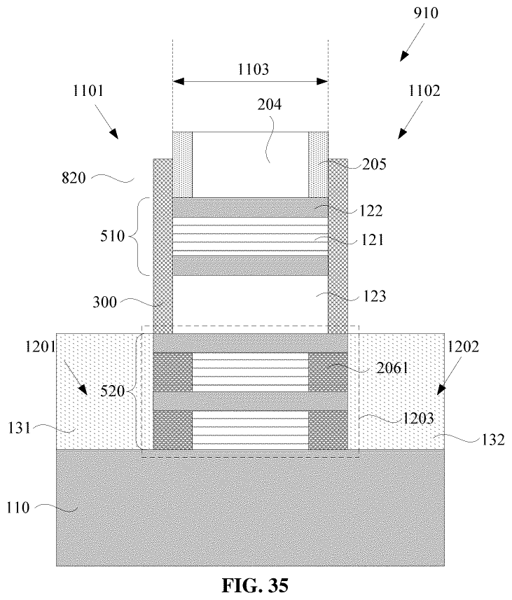

In an embodiment of the present disclosure, after the first bottom source 131 and the first bottom drain 132 are formed, the first epitaxial barrier layer 810 may be removed, to form the second bottom source 133 in the bottom source region 1201 of the second fin structure 920 and to form the second bottom drain 134 in the bottom drain region 1202 of the second fin structure 920. In the process of forming the second bottom source 133 and the second bottom drain 134, a second epitaxial barrier layer 820 may be formed on a surface of the first fin structure 910, to prevent damage to the first fin structure 910. The second epitaxial barrier layer 820 covers the first fin structure 910, referring to FIG. 34. After the first fin structure 910 is protected from being damaged by the second epitaxial barrier layer 820, the second bottom source 133 may be formed in the bottom source region 1201 of the second fin structure 920, and the second bottom drain 134 may be formed in the bottom drain region 1202 of the second fin structure 920, referring to FIG. 33.

In step S1045, the second epitaxial barrier layer 820 is removed, referring to FIGS. 35 and 36.

In an embodiment of the present disclosure, after the second bottom source 133 and the second bottom drain 134 are formed, the second epitaxial barrier layer 820 may be removed.

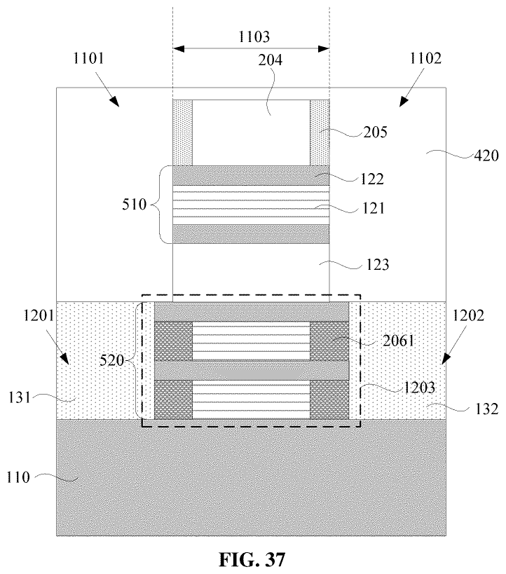

In step S105, a ground connection layer is formed on the first bottom source, a first storage bottom electrode is formed on the first bottom drain and the second bottom source, a power connection layer is formed on the second bottom drain, the buried power connection layer is electrically connected to the power connection layer, the buried ground connection layer is electrically connected to the ground connection layer, and the first storage bottom electrode is electrically connected to the first bottom drain and the second bottom source, referring to FIGS. 37, 38 to 45, 46 and 47.

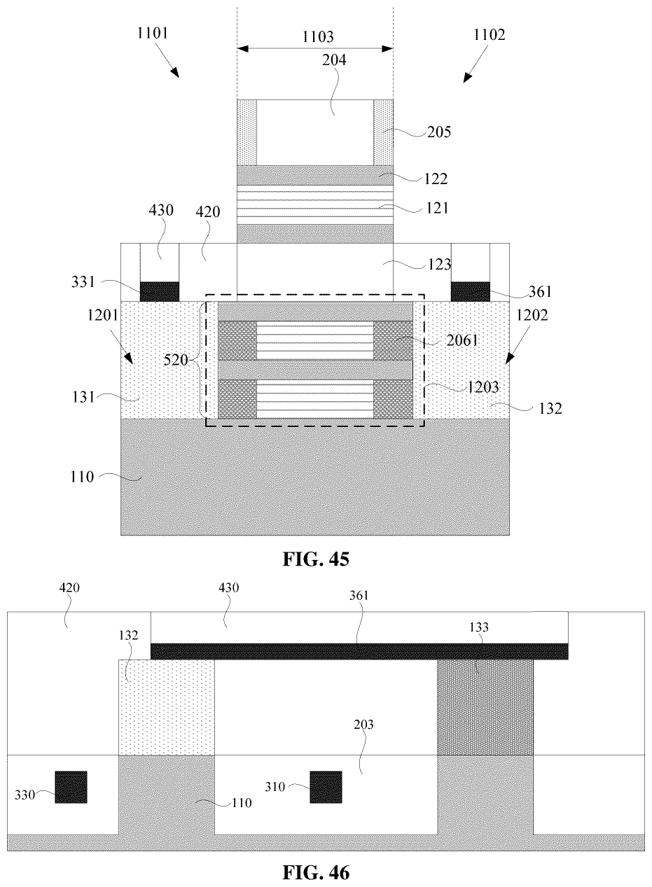

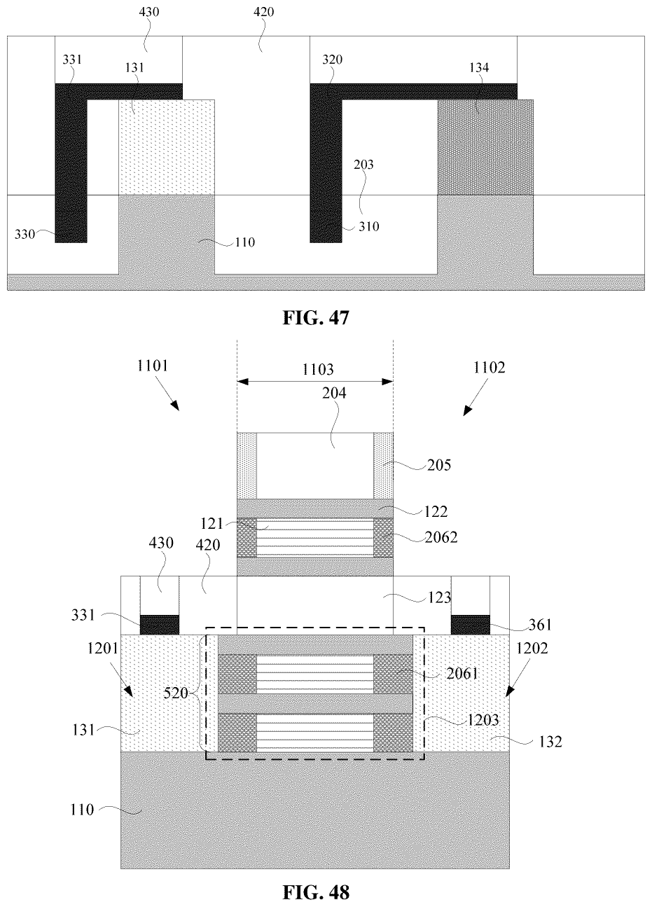

In an embodiment of the present disclosure, considering that two transistors stacked vertically are formed subsequently and transistors formed by different fin structures require electrical lead-out, after the first bottom source 131, the first bottom drain 132, the second bottom source 133 and the second bottom drain 134 are formed, a ground connection layer 331 may be formed on the first bottom source 131, and the buried ground connection layer 330 is electrically connected to the ground connection layer 331, as shown in FIGS. 45 and 47. A first storage bottom electrode 361 is formed on the first bottom drain 132 and the second bottom source 133, as shown in FIG. 46. The first storage bottom electrode 361 is electrically connected to the first bottom drain 132 and the second bottom source 133, to electrically connect transistors in different fin structures. A power connection layer 320 is formed on the second bottom drain 134, and the buried power connection layer 310 is electrically connected to the power connection layer 320, referring to FIG. 47. The specific formation process is described in detail below.

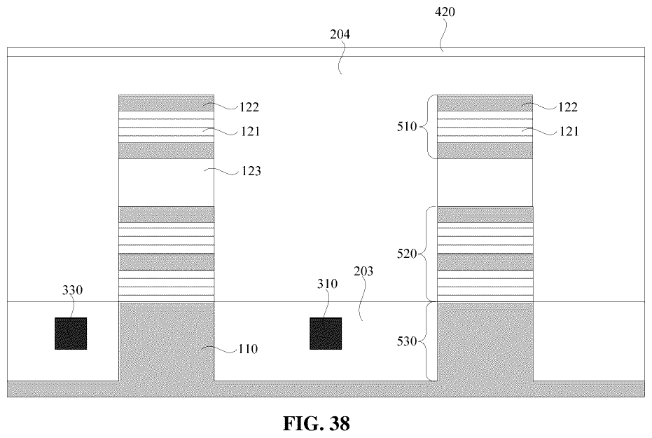

In step S1051, a first dielectric layer 420 is formed to overlay the top structure 510, referring to FIGS. 37 and 38.

In an embodiment of the present disclosure, after the first bottom source 131, the first bottom drain 132, the second bottom source 133, and the second bottom drain 134 are formed, the third spacer 300 may be removed, then a dielectric material may be deposited and planarization may be performed to form the first dielectric layer 420. The first dielectric layer 420 overlays the top structure 510, as shown in FIGS. 37 and 38.

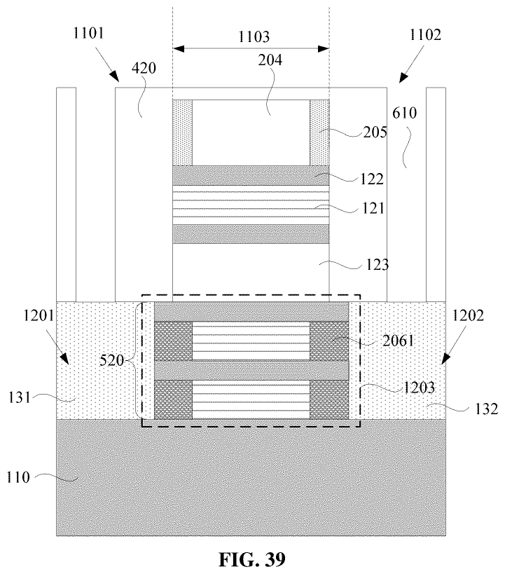

In step S1052, the first dielectric layer 420 at two sides of the top structure 510 is etched, to form a first groove 610; and the first bottom source 131, the first bottom drain 132, the second bottom source 133, and the second bottom drain 134 are exposed by the first groove 610, referring to FIGS. 39 and 40.

In an embodiment of the present disclosure, after the first dielectric layer 420 is formed, the first dielectric layer 420 on two sides of the top structure 510 may be etched to expose the first bottom source 131, the first bottom drain 132, the second bottom source 133, and the second bottom drain 134, to form the first groove 610. The first bottom source 131, the first bottom drain 132, the second bottom source 133, and the second bottom drain 134 are exposed by the first groove 610, referring to FIGS. 39 and 40. The buried ground connection layer 330 and the buried power connection layer 310 are also exposed by the first groove 610, referring to FIG. 40.

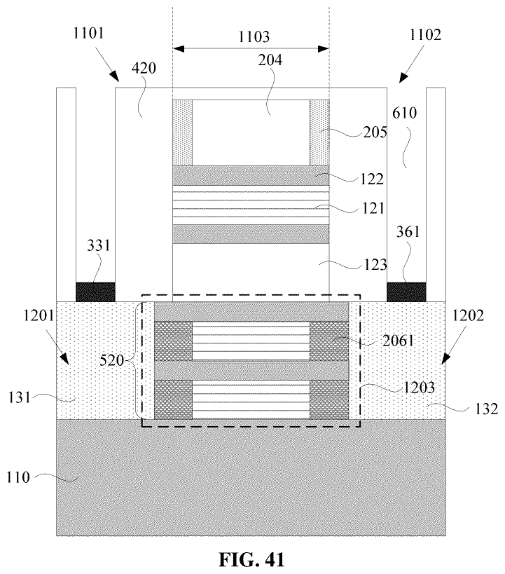

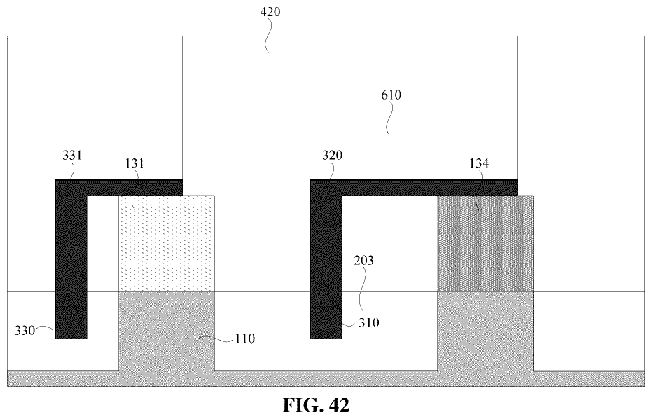

In step S1053, the ground connection layer 331 is formed on the first bottom source 131 exposed by the first groove 610, the first storage bottom electrode 361 is formed on the first bottom drain 132 and the second bottom source 133 that are exposed by the first groove 610, and the power connection layer 320 is formed on the second bottom drain 134 exposed by the first groove 610, referring to FIGS. 41 and 42.

In an embodiment of the present disclosure, after the first groove 610 exposing the first bottom source 131, the first bottom drain 132, the second bottom source 133, and the second bottom drain 134 is formed, the ground connection layer 331 may be formed on the first bottom source 131 exposed by the first groove 610, the first storage bottom electrode 361 may be formed on the first bottom drain 132 and the second bottom source 133 that are exposed by the first groove 610, and the power connection layer 320 may be formed on the second bottom drain 134 exposed by the first groove 610, as shown in FIGS. 41 and 42.

In practice, a bottom word line connection layer and a bottom bit line connection layer are also formed while forming the ground connection layer 331, the first storage bottom electrode 361, and the power connection layer 320, to perform word line connection and bit line connection.

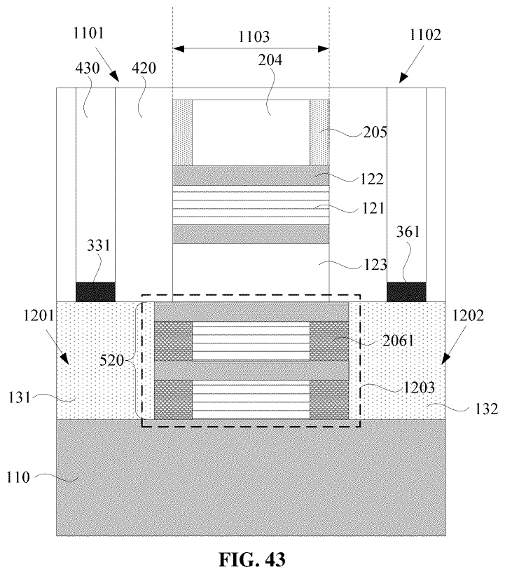

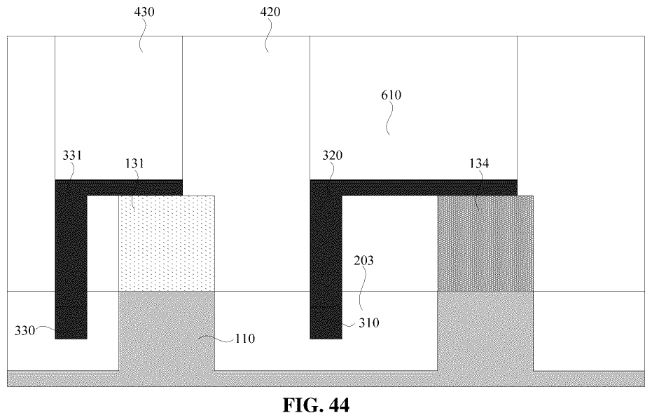

In step S1054, a second dielectric layer 430 is formed in the first groove 610, referring to FIGS. 43 and 44.

In an embodiment of the present disclosure, after the ground connection layer 331, the first storage bottom electrode 361, and the power connection layer 320 are formed, a dielectric material may be deposited in the first groove 610, and then planarization may be performed to form the second dielectric layer 430, referring to FIGS. 43 and 44. The materials of the first dielectric layer 420 and the second dielectric layer 430 may be the same.

In step S1055, the first dielectric layer 420 and the second dielectric layer 430 are etched, such that surfaces of the first dielectric layer 420 and the second dielectric layer 430 that are opposite to the substrate 110 is flush with a surface of the buffer layer 123 opposite to the substrate 110, referring to FIGS. 45, 46, and 47.

In an embodiment of the present disclosure, after the second dielectric layer 430 is formed, the first dielectric layer 420 and the second dielectric layer 430 may be etched back to the surface of the buffer layer 123 opposite to the substrate 110. The etched first dielectric layer 420 and the etched second dielectric layer 430 overlay the ground connection layer 331, the first storage bottom electrode 361, and the power connection layer 320, as shown in FIGS. 45, 46, and 47.

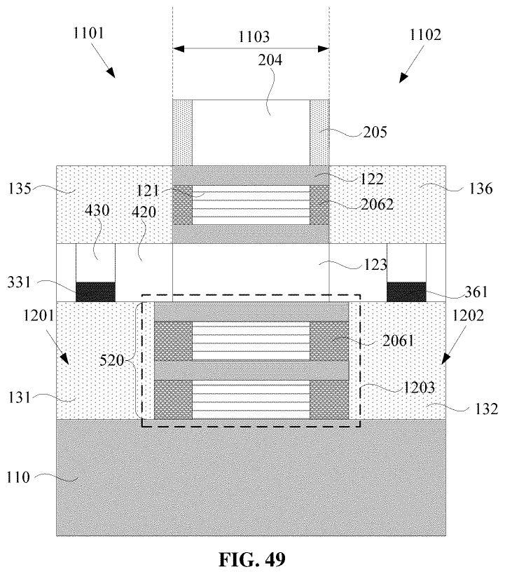

In step S106, a first top source is formed above the ground connection layer of the first fin structure, a first top drain is formed above the first storage bottom electrode of the first fin structure, a second top source is formed above the first storage bottom electrode of the second fin structure, and a second top drain is formed above the power connection layer of the second fin structure, referring to FIGS. 48 and 49.

In an embodiment of the present disclosure, after the ground connection layer 331, the first storage bottom electrode 361, and the power connection layer 320 are formed, top sources and top drains may be formed on the ground connection layer 331, the first storage bottom electrode 361, and the power connection layer 320, to form the source and the drain of an upper transistor in two transistors stacked vertically. Specifically, the first top source 135 may be formed above the ground connection layer 331 of the first fin structure 910, and the first top drain 136 may be formed above the first storage bottom electrode 361 of the first fin structure 910, referring to FIG. 49. The second top source is formed above the first storage bottom electrode 361 of the second fin structure 920, and a second top drain is formed on the power connection layer 320 of the second fin structure 920. Specifically, the first top source 135, the first top drain 136, the second top source, and the second top drain may be located on the first dielectric layer 420 and the second dielectric layer 430.

In an embodiment of the present disclosure, before forming the first top source 135, the first top drain 136, the second top source and the second top drain, a top inner spacer may be formed on a sidewall of the fin along the Y-Y′ direction, and the specific process is as follows.

In step S1061, a concave structure is formed.

In an embodiment of the present disclosure, selective etching is performed on the first semiconductor layer 121 in the top structure 510 in the Y-Y′ direction. That is, only the first semiconductor layer 121 is etched without damaging the second semiconductor layer 122, and thus a concave structure is formed of the etched first semiconductor layer 121 and the second semiconductor layer 122 in the Y-Y′ direction. That is, pull-back etching is performed to etch a part of the first semiconductor layer 121 in a direction from the top source region 1101 and the top drain region 1102 to the top channel region 1103.

In step S1062, a top inner spacer 2062 is formed, referring to FIG. 48.

In an embodiment of the present disclosure, after the first semiconductor layer 121 is etched, a dielectric material is deposited on the top structure 510 in the top channel region 1103, that is, on an outer periphery of the fin, and the dielectric material is etched to form the top inner spacer 2062. The top inner spacer 2062 is flush with the second semiconductor layer 122 in the direction perpendicular to the plane where the substrate 110 is located. That is, the concave structure formed through etching in S1061 is filled up with the top inner spacer 2062. The material of the top inner spacer 2062 may be silicon nitride or silicon oxide.

In an embodiment, for different types of semiconductor devices, a source-drain material may be varied. For a P-type semiconductor device, the source-drain material is boron-doped silicon germanium, that is, SiGe:B. For an N-type semiconductor device, the source-drain material is carbon-doped silicon, that is, Si:C. Considering the formation of two transistors which are stacked vertically and have the same doping type, the two fin structures are to form transistors that have different doping types subsequently, different source-drain materials may be employed to form the source and drain of the first fin structure 910 and the source and drain of the second fin structure 920. The specific process flow of forming the first bottom source 131, the first bottom drain 132, the second bottom source 133, and the second bottom drain 134 is similar to that of forming the first top source 135, the first top drain 136, the second top source, and the second top drain, which will not be repeated herein.

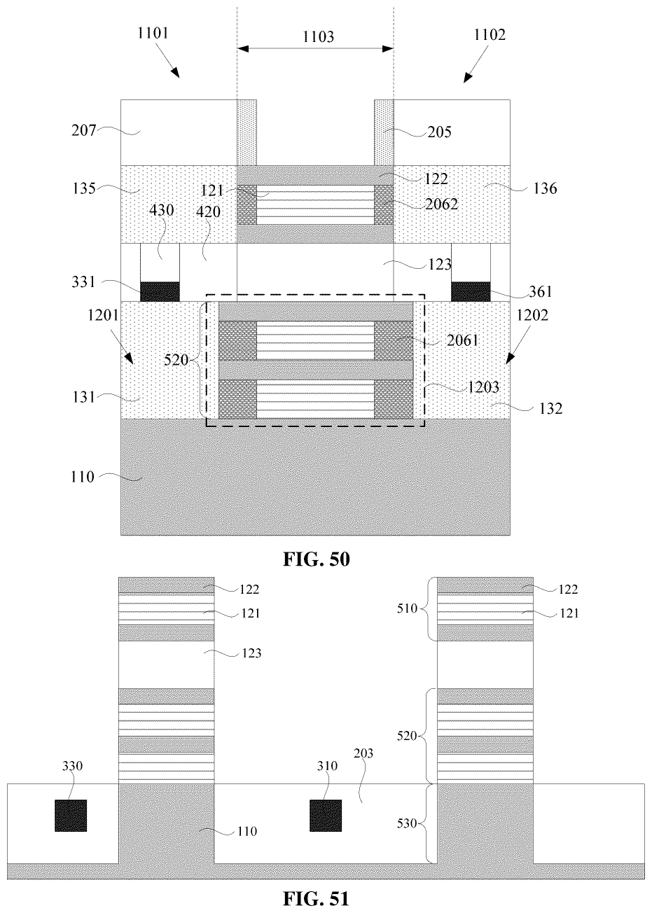

In step S107, the first semiconductor layer in the top channel region and the bottom channel region is removed, to form multiple to-be-filled gaps between the second semiconductor layers, referring to FIGS. 50 to 53.

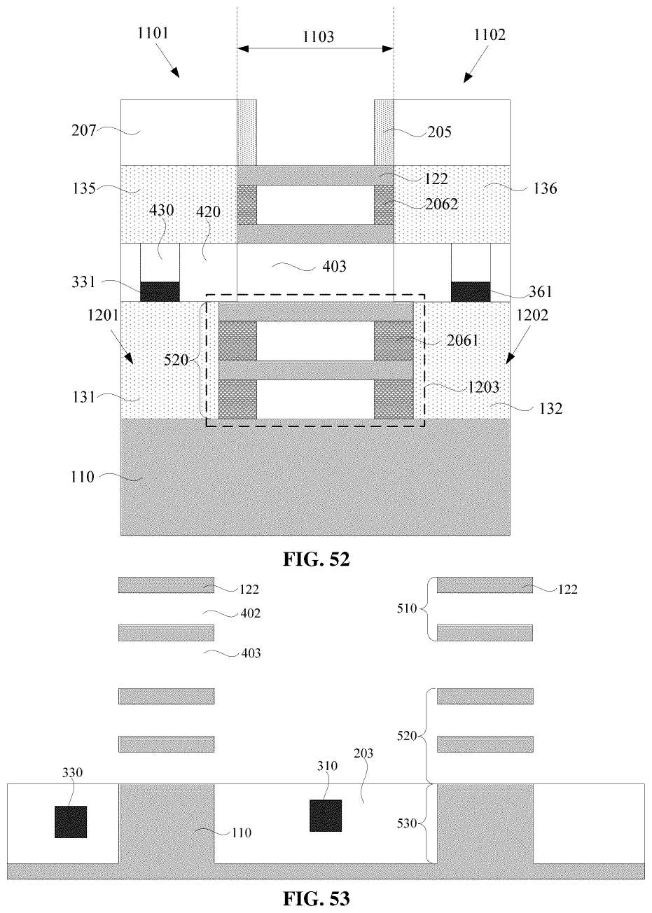

In an embodiment of the present disclosure, the first semiconductor layer 121 in the top channel region 1103 and the bottom channel region 1203 may be removed, that is, a nanosheet channel release process is performed, to form multiple to-be-filled gaps between the second semiconductor layers 122, referring to FIGS. 52 and 53.

In an embodiment, selective etching may be performed on the first semiconductor layers 121 in the stacked structures in the top channel region 1103 and the bottom channel region 1203, to release nanosheet channels. That is, the stacked structure exposed on the fin is processed. The first semiconductor layer 121 in each layer is removed. That is, the first semiconductor layer 121 serves as a sacrificial layer. The nanosheets formed by the second semiconductor layer 122 are released.

The buffer layer 123 is also removed while removing the first semiconductor layer 121. That is, the multiple formed to-be-filled gaps 402 include isolation gaps 403 formed by removing the buffer layer 123, referring to FIGS. 52 and 53.

In an embodiment of the present disclosure, for different types of devices, several possible implementations for releasing the nanosheet channel are as follows.

In a first possible implementation, for both P-type and N-type semiconductor devices, the material of the first semiconductor layer 121, which serves as the sacrificial layer, is silicon germanium. By selectively removing the silicon germanium, the second semiconductor layer 122, which is formed of silicon, is retained to form a silicon-stacked nanosheet stacked device. In the selective removal process, an etchant that can selectively etch silicon germanium at a faster rate relative to silicon may be used.

In a second possible implementation, for a P-type semiconductor device, the material of the first semiconductor layer 121, which serves as the sacrificial layer, is silicon. By selectively removing the silicon, the second semiconductor layer 122, which is formed of silicon germanium, is retained to form a silicon-germanium-stacked nanosheet stacked device. In the selective removal process, an etchant that can selectively etch silicon at a faster rate relative to silicon germanium may be used.

In a third possible implementation, for an N-type semiconductor device, the material of the first semiconductor layer 121, which serves as the sacrificial layer, is silicon germanium. By selectively removing the silicon germanium, the second semiconductor layer 122, which is formed of silicon, is retained to form a silicon-stacked nanosheet stacked device. In the selective removal process, an etchant that can selectively etch silicon germanium at a faster rate relative to silicon may be used.

In an embodiment of the present disclosure, before the first semiconductor layer 121 in the top channel region 1103 and the bottom channel region 1203 may be removed, the dummy gate 204 is removed, and the specific process flow is as follows.

In step S1071, the dummy gate 204 is removed, referring to FIGS. 50 and 51.

In an embodiment of the present disclosure, a spacer layer 207 may be deposited on surfaces of the dummy gate 204, the first top source 135, and the first top drain 136, to prevent a short circuit caused by interconnection between the dummy gate 204 and the first top source 135 or between the dummy gate 204 and the first top drain 136 subsequently. Chemical mechanical polishing is performed on the spacer layer 207 to flatten the surface thereof. Then, as shown in FIGS. 50 and 51, the dummy gate 204 formed of polysilicon or amorphous silicon is etched by selective etching or corroded by corrosion process, that is, the dummy gate 204 is removed.

In an embodiment of the present disclosure, after multiple to-be-filled gaps 402 are formed, an interface layer may be formed on the surface of the second semiconductor layer 122. An interface between the interface layer and the second semiconductor layer 122 may be passivated. In an embodiment, the material of the interface layer may be silicon oxide.

In an embodiment of the present disclosure, after the interface layer is formed, a high-k dielectric layer may also be formed on the surface of the interface layer, and the high-k dielectric layer surrounds the surface of the interface layer. In an embodiment, the material of the high-k dielectric layer may be any one of HfO₂, HfSiOₓ, HfON, HfSiON, HfAlOx, HfLaOₓ, Al₂O₃, ZrO₂, ZrSiOₓ, Ta₂O₅, La₂O₃, or a combination thereof.

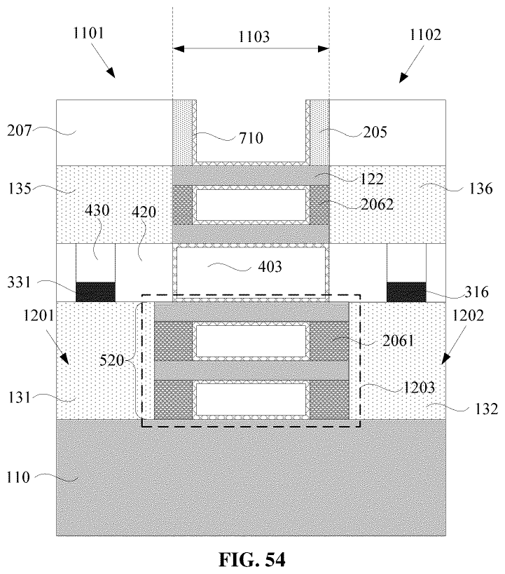

In step S108, a first-type work function layer is formed in the to-be-filled gaps of the first fin structure, and a second-type work function layer is formed in the to-be-filled gaps of the second fin structure, multiple to-be-filled gaps are filled with a gate, the gate surrounds the second semiconductor layers, and a top channel structure and a bottom channel structure are formed by a stack of multiple second semiconductor layers, referring to FIGS. 54 to 63.

In an embodiment of the present disclosure, considering that different types of transistors with different fin structures can be formed using different types of work function layers, the first-type work function layer 720 may be formed in the to-be-filled gaps 402 of the first fin structure 910, and the second-type work function layer 710 may be formed in the to-be-filled gaps 402 of the second fin structure 920. The multiple to-be-filled gaps 402 are then filled with a gate 160. The specific process is described in detail below.

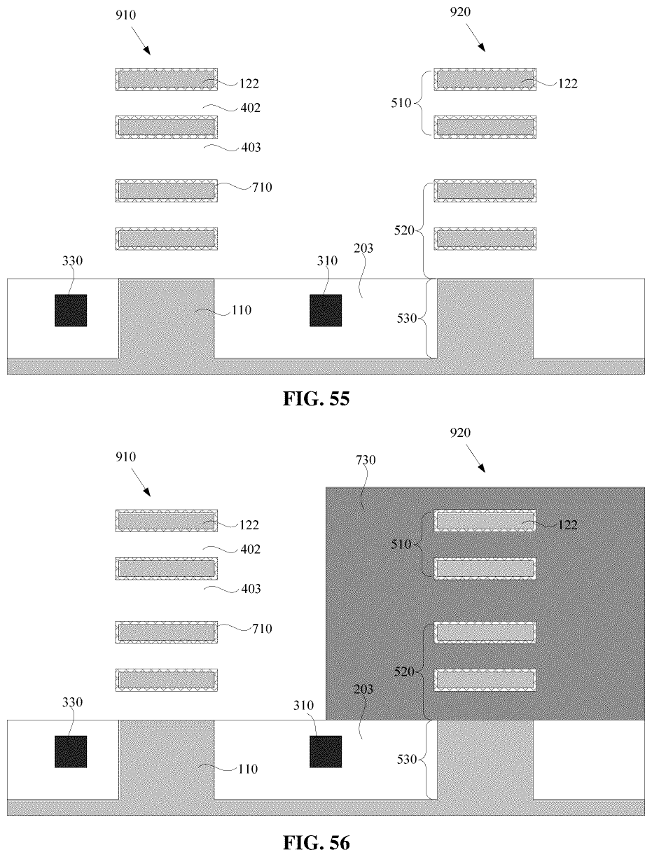

In step S1081, the second-type work function layer 710 is formed in the to-be-filled gaps 402 of the first fin structure 910 and the second fin structure 920, referring to FIGS. 54 and 55.

In an embodiment of the present disclosure, the second-type work function layer 710 may be formed in all of the to-be-filled gaps 402, and the second-type work function layer 710 surrounds the surface of the high-k dielectric layer. In an embodiment, the second-type work function layer 710 is a P-type work function layer (P-WFL).

In step S1082, a first isolation protective layer 730 is formed on the second fin structure 920, and the second-type work function layer in the to-be-filled gaps 402 of the first fin structure 910 is removed.

In an embodiment of the present disclosure, since the first fin structure 910 and the second fin structure 920 are used to form different types of transistors, the first-type work function layer 720 should be formed in the first fin structure 910. Thus, the first isolation protective layer 730 is formed on the second fin structure 920, and then the second-type work function layer 710 in the to-be-filled gaps 402 of the first fin structure 910 is removed. In an embodiment, the first-type work function layer 720 is an N-type work function layer (N-WFL). The second-type work function layer 710 in the to-be-filled gaps 402 of the first fin structure 910 may be removed by corrosion process.

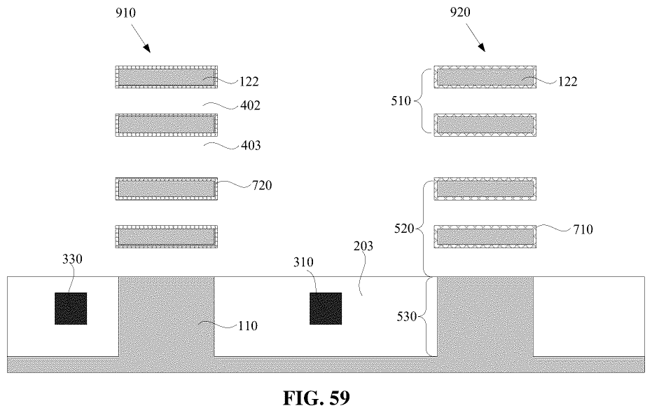

In step S1083, a first-type work function layer 720 is formed in the to-be-filled gaps 402 of the first fin structure 910, referring to FIGS. 58 and 59.

In an embodiment of the present disclosure, the second fin structure 920 may be protected by the first isolation protective layer 730, to form the first-type work function layer 720 in the to-be-filled gaps 402 of the first fin structure 910 without damaging the second fin structure 920.

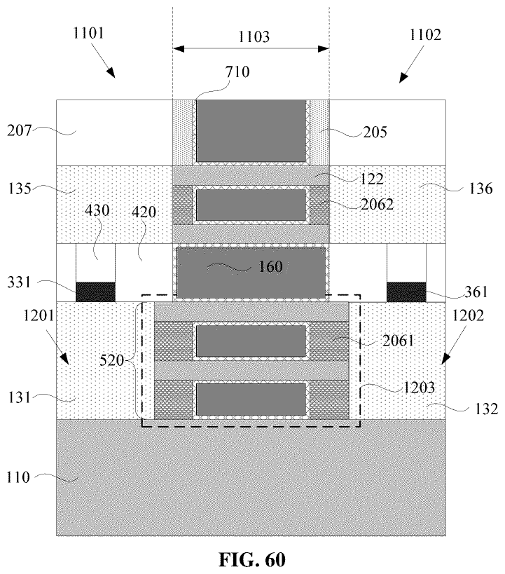

In step S1084, the first isolation protective layer 730 is removed, referring to FIGS. 60 and 61.

In an embodiment of the present disclosure, the first isolation protective layer 730 may be removed after the first-type work function layer 720 and the second-type work function layer 710 are formed.

In practice, the first isolation protective layer 730 may be removed first, and then the first-type work function layer 720 is formed in all of the to-be-filled gaps 402. That is, the second-type work function layer 710 may be formed first in the to-be-filled gaps 402 of the second fin structure 920, and then the first-type work function layer 720 may be formed.

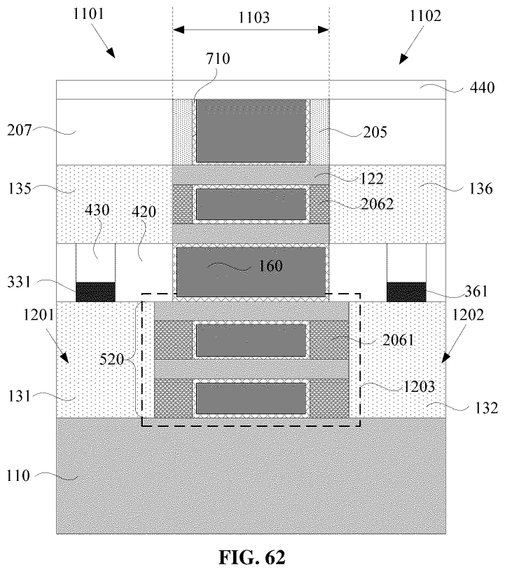

In an embodiment of the present disclosure, after the nanosheet channel is released, multiple to-be-filled gaps 402 exist between multiple second semiconductor layers 122. Multiple to-be-filled gaps 402 may be filled by a gate 160, and the gate 160 surrounds the second semiconductor layer 122 to form a gate-all-round structure. In an embodiment, the gate 160 surrounds the first-type work function layer 720 and the second-type work function layer 710. A stack of multiple second semiconductor layers 122 forms a top channel structure and a bottom channel structure, that is, a nanosheet channel of a complementary field-effect transistor is formed, referring to FIGS. 62 and 63.

In practice, in addition to forming the gate 160 in the to-be-filled gaps 402, the gate 160 also fill the spacer layer 207 and the space left after the dummy gate 204 is removed. Chemical mechanical polishing and planarization are performed on the gate 160 overlaying the spacer layer 207.

In step S109, a first storage top electrode is formed on the first top drain, the first storage top electrode is electrically connected to the first storage bottom electrode, a top power connection layer is formed on the second top source, and a second storage top electrode is formed on the second top drain, referring to FIGS. 64, 65 to 66, and 67.

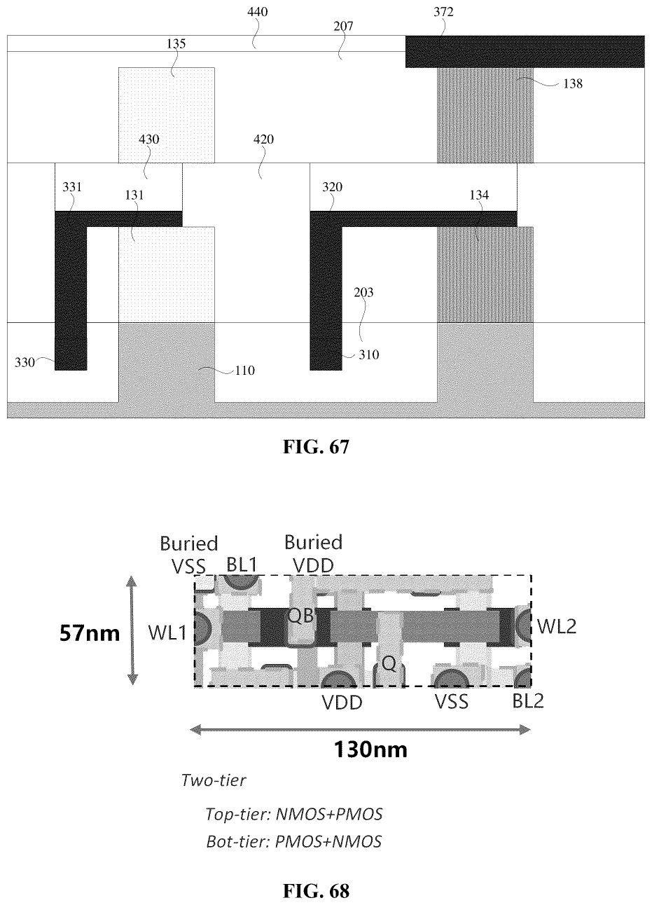

In an embodiment of the present disclosure, after the gate 160 is formed, a first storage top electrode 362, a second storage top electrode 372, and a top power connection layer 321 may be formed on the first top source 135, the first top drain 136, the second top source, and the second top drain. The first storage top electrode 362 is electrically connected to the first storage bottom electrode 361, referring to FIGS. 66 and 67. The specific formation process is described in detail below.

In step S1091, a third dielectric layer 440 is formed on the first top source 135, the first top drain 136, the second top source, and the second top drain.

In an embodiment of the present disclosure, after the first top source 135, the first top drain 136, the second top source, and the second top drain are formed, a dielectric material may be deposited, and planarization may be performed, to form the third dielectric layer 440. The third dielectric layer 440 overlays the first top source 135, the first top drain 136, the second top source, and the second top drain.

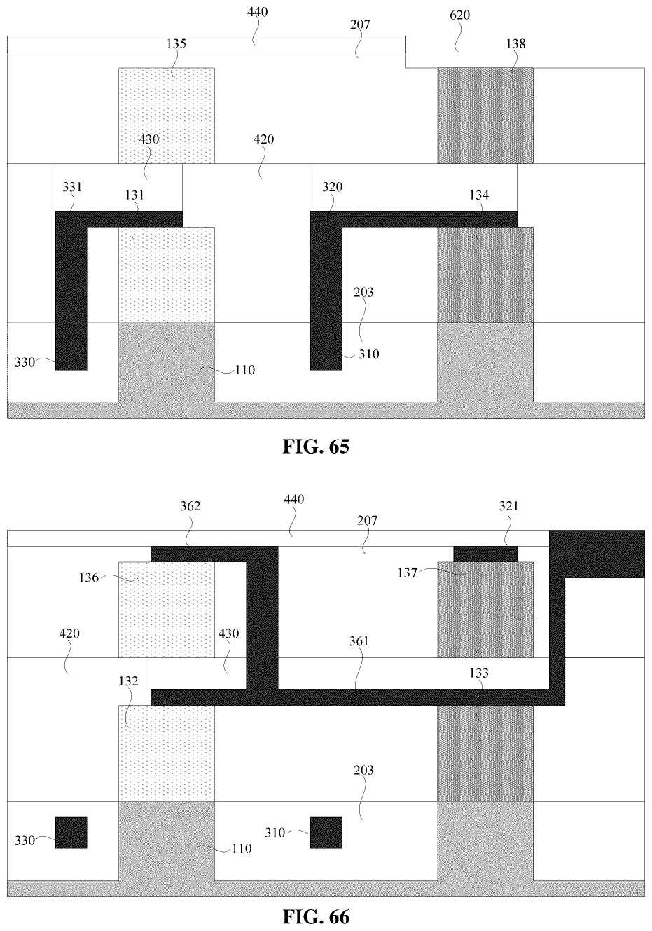

In step S1092, the third dielectric layer 440 is etched to form a second groove 620, and the first top drain 136, the second top source, and the second top drain are exposed by the second groove 620, referring to FIGS. 64 and 65.

In an embodiment of the present disclosure, after the third dielectric layer 440 is formed, the third dielectric layer 440 on two sides of the top structure 510 may be etched to expose the first top drain 136, the second top source, and the second top drain, to form the second groove 620. The first top drain 136, the second top source, and the second top drain are exposed by the second groove 620, referring to FIGS. 64 and 65. In FIG. 64, the second top source is denoted by 137. In FIG. 65, the second top drain is denoted by 138. The first storage bottom electrode 361 is also exposed by the second groove 620, referring to FIG. 64.

In step S1093, the first storage top electrode 362 is formed on the first top drain 136 exposed by the second groove 620, the top power connection layer 321 is formed on the second top source exposed by the second groove 620, and the second storage top electrode 372 is formed on the second top drain exposed by the second groove 620, referring to FIGS. 66 and 67.

In an embodiment of the present disclosure, after the second groove 620 is formed, the first storage top electrode 362 may be formed on the first top drain 136 exposed by the second groove 620, referring to FIG. 66. The top power connection layer 321 is formed on the second top source exposed by the second groove 620, referring to FIG. 66. In FIG. 66, the second top source is denoted by 137. The second storage top electrode 372 is formed on the second top drain exposed by the second groove 620, referring to FIG. 67. In FIG. 67, the second top drain is denoted by 138. In addition, a top word line connection layer and a top bit line connection layer are formed on the first top source 135, the first top drain 136, the second top source, and the second top drain that are exposed by the second groove 620.

Referring to FIG. 66, the first storage top electrode 362 is electrically connected to the first storage bottom electrode 361, and the first storage bottom electrode 361 is electrically connected to the first bottom drain 132 and the second bottom source 133.

In practice, a first storage electrode includes the first storage top electrode 362 and the first storage bottom electrode 361. The first storage electrode may be a Q storage electrode. A second storage electrode includes the second storage top electrode 372 and a second storage bottom electrode 371. The second storage electrode may be a QB storage electrode.

In the complementary field-effect transistor according to the present disclosure, the same work function layer is simultaneously formed on vertically stacked transistors corresponding to one fin structure, and then horizontal transistors are connected with each other through planar interconnection and vertical vias, to form lateral complementary transistors. According to the present disclosure, compared with a delamination process of forming vertically stacked transistors having different types of work function layers, a highly controllable partition process can be achieved through a simple lateral partition process for horizontal work function layers, and PMOS and NMOS can be separated completely, thereby preventing sticking of the NMOS and the PMOS. According to the present disclosure, by adjusting the layout structure and providing laterally complementary CFETs, the process difficulty can be reduced compared with providing different types of transistors stacked vertically, thereby improving process controllability. Compared with the vertical arrangement of complementary CFETs, the area of the storage unit in the static random-access memory can be reduced from 114 nm×76 nm to 130 nm×57 nm, referring to FIG. 68. The lateral complementary transistors have vertically asymmetric buried VDD or asymmetric buried VSS, and also have an asymmetric word line lead-out structure and an asymmetric bit line lead-out structure. The specific value of the area reduction of the storage unit shown in FIG. 68 is merely an example, and the actual extent of the area reduction in the present disclosure is not limited.

In addition to the method for manufacturing a complementary field-effect transistor according to the above embodiments, a complementary field-effect transistor is provided according to an embodiment of the present disclosure, and the operation principle thereof is described in detail below in conjunction with the drawings.

Reference is made to FIG. 66, and 67, which are schematic cross-sectional views illustrating a complementary field-effect transistor according to an embodiment of the present disclosure.

The complementary field-effect transistor according to the present embodiment includes: a substrate 110; a first top source 135, a first top drain 136, a first top channel structure, a second top source 137, a second top drain 138, a second top channel structure, a first bottom source 131, a first bottom drain 132, a first bottom channel structure, a second bottom source 133, a second bottom drain 134, and a second bottom channel structure which are provided on a surface of the substrate 110; where a first-type work function layer 720 is provided on surfaces of multiple nanosheets included in the first top channel structure and the first bottom channel structure, a second-type work function layer 710 is provided on surfaces of multiple nanosheets included in the second top channel structure and the second bottom channel structure; and a gate 160 surrounding the nanosheets.

A ground connection layer 331 is provided on the first bottom source 131. A first storage bottom electrode 361 is provided on the first bottom drain 132 and the second bottom source 133. A power connection layer 320 is provided on the second bottom drain 134. A buried power connection layer 310 is electrically connected to the power connection layer 320, and a buried ground connection layer 330 is electrically connected to the ground connection layer 331. The first storage bottom electrode 361 is electrically connected to the first bottom drain 132 and the second bottom source 133. A first storage top electrode 362 is provided on the first top drain 136, and the first storage top electrode 362 is electrically connected to the first storage bottom electrode 361. A top power connection layer 321 is provided on the second top source 137, and a second storage top electrode 372 is provided on the second top drain 138.

In an embodiment, the first-type work function layer 720 is an N-type work function layer, and the second-type work function layer 710 is a P-type work function layer.

In an embodiment, the materials of the first top source 135 and the first bottom source 131 at least include Si, Si:C, or Si:P, and the materials of the first top drain 136 and the first bottom drain 132 at least include SiGe, Si:B, or Ge.

Based on the complementary field-effect transistor based on the above embodiments, a static random-access memory is further provided according to an embodiment of the present disclosure. The static random-access memory includes multiple storage units, and each of the storage units includes the complementary field-effect transistor according to any one of the above embodiments.

In an embodiment of the present disclosure, the storage unit of the static random-access memory has a bit storage structure of a lower PD and an upper AC as well as an upper PD and a lower AC that is bilaterally symmetric and vertically symmetric.

Based on the SRAM unit according to the above embodiments, a method for manufacturing the SRAM unit is further provided according to an embodiment of the present disclosure. The operation principle thereof is described in detail below in conjunction with the drawings.

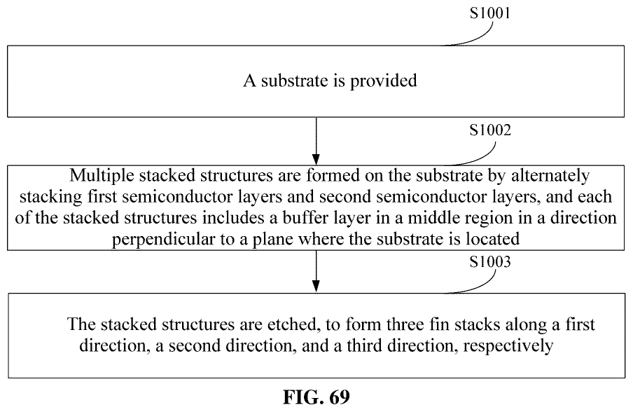

Reference is made to FIG. 69, which is a flowchart illustrating a method for manufacturing an SRAM unit according to an embodiment of the present disclosure.

In step S1001, a substrate is provided.

In step S1002, multiple stacked structures are formed on the substrate by alternately stacking first semiconductor layers and second semiconductor layers, and each of the stacked structures includes a buffer layer in a middle region in a direction perpendicular to a plane where the substrate is located.

In an embodiment of the present disclosure, a substrate 110 may be a semiconductor substrate, such as a bulk silicon substrate, and the substrate 110 may be doped to obtain a P-type semiconductor substrate, such as a P-type silicon substrate, or an N-type semiconductor substrate, such as an N-type silicon substrate. The stacked structure that is formed by alternately stacking the first semiconductor layers 121 and the second semiconductor layers 122 may be formed on one side of the substrate 110, referring to FIGS. 9 and 10.

In step S1003, the stacked structures are etched, to form three fin stacks along a first direction, a second direction, and a third direction, respectively.

In an embodiment of the present disclosure, the stacked structures are etched, to form three fin stacks along the first direction, the second direction, and the third direction, respectively. The first direction, the second direction, and the third direction are parallel, and the first direction, the second direction, and the third direction are arranged along the Y-Y′ direction.

In step S1004, the fin stacks along the first direction and the third direction are processed to form a first complementary field-effect transistor (CFET) and a third CFET, the fin stack along the second direction is processed to form a second CFET, and the second CFET is provided between the first CFET and the third CFET. Upper transistors and lower transistors of both the first CFET and the third CFET are N-type transistors, and an upper transistor and a lower transistor of the second CFET are P-type transistors.

In an embodiment of the present disclosure, after three fin stacks are obtained, the fin stacks along the first direction and the third direction are processed to form the first complementary field-effect transistor (CFET) and the third CFET, the fin stack along the second direction is processed to form the second CFET, and the second CFET is provided between the first CFET and the third CFET. Upper transistors and lower transistors of both the first CFET and the third CFET are N-type transistors, and an upper transistor and a lower transistor of the second CFET are P-type transistors.

The embodiments in this specification are described in a progressive manner. Various embodiments may refer to each other for the same or similar parts, and each embodiment focuses on the difference from other embodiments. In particular, the method embodiment is virtually similar to the structure embodiment, and therefore is described relatively briefly. For relevant details, reference can be made to the corresponding description of the structure embodiment. The above structure embodiments are merely illustrative, which can be understood and implemented by those skilled in the art without creative efforts.

Only preferred embodiments of the present disclosure are described above. Although the present disclosure is disclosed above in conjunction with the preferred embodiments, the preferred embodiments are not intended to limit the present disclosure. Those skilled in the art, without departing from the scope of the technical solutions of the present disclosure, may make variations and modifications to the technical solutions of the present disclosure based on the above disclosed method and technical solutions, or modify the embodiments to equivalent embodiments. Therefore, all simple modifications, equivalent changes and modifications made to the above embodiments based on the technical essence of the present disclosure without departing from the technical solutions of the present disclosure fall within the protection scope of the technical solutions of the present disclosure.

1. An SRAM unit, comprising: a first complementary field effect transistor (CFET), a second CFET and a third CFET; wherein the first CFET, the second CFET and the third CFET are arranged in parallel and have parallel channel directions, the second CFET is provided between the first CFET and the third CFET, upper transistors and lower transistors of both the first CFET and the third CFET are N-type transistors, and an upper transistor and a lower transistor of the second CFET are P-type transistors, and
the upper transistor of the first CFET and the lower transistor of the third CFET serve as gate transistors.

2. The SRAM unit according to claim 1, wherein
the first CFET comprises: a first top source, a first top drain, a first top channel structure, a first bottom source, a first bottom drain, and a first bottom channel structure;
the second CFET comprises: a second top source, a second top drain, a second top channel structure, a second bottom source, a second bottom drain, and a second bottom channel structure;
the third CFET comprises: a third top source, a third top drain, a third top channel structure, a third bottom source, a third bottom drain, and a third bottom channel structure; and
the SRAM unit comprises a plurality of gates, wherein the plurality of gates respectively surround a nanosheet comprised in the first top channel structure, a nanosheet comprised in the first bottom channel structure, a nanosheet comprised in the second top channel structure, a nanosheet comprised in the second bottom channel structure, a nanosheet comprised in the third bottom channel structure, and a nanosheet comprised in the third bottom channel structure.

3. The SRAM unit according to claim 2, wherein the plurality of gates comprise a top gate that surrounds the nanosheets comprised in the top channel structures for the first CFET, the second CFET and the third CFET; and a bottom gate that surrounds the nanosheets comprised in the bottom channel structures for the first CFET, the second CFET and the third CFET;
the bottom gates of the first CFET and the second CFET are connected with each other; and
the top gates of the second CFET and the third CFET are connected with each other.

4. The SRAM unit according to claim 2, wherein
a first-type work function layer is provided on surfaces of the nanosheets comprised in the first top channel structure and the first bottom channel structure, a second-type work function layer is provided on surfaces of the nanosheets comprised in the second top channel structure and the second bottom channel structure, and the first-type work function layer is provided on surfaces of the nanosheets comprised in the third top channel structure and the third bottom channel structure.

5. The SRAM unit according to claim 4, wherein the first-type work function layer is an N-type work function layer, and the second-type work function layer is a P-type work function layer.

6. The SRAM unit according to claim 2, wherein
a ground connection layer is provided on the first bottom source, a buried power connection layer is provided between the first CFET and the second CFET, a buried ground connection layer is provided at a side of a substrate of the first CFET that is away from the second CFET, a power connection layer is provided on the second bottom drain, the buried power connection layer is electrically connected to the power connection layer, and the buried ground connection layer is electrically connected to the ground connection layer.

7. The SRAM unit according to claim 6, wherein a first storage bottom electrode is provided on the first bottom drain, and the first storage bottom electrode is electrically connected to the first bottom drain and the second bottom source.

8. The SRAM unit according to claim 6, wherein
a first storage top electrode is provided on the first top drain, and the first storage top electrode is electrically connected to the first storage bottom electrode.

9. The SRAM unit according to claim 8, wherein the first storage top electrode is connected to the first top drain of the first CFET, a top gate of the second CFET, and a top gate of the third CFET.

10. The SRAM unit according to claim 6, wherein
a top power connection layer is provided on the second top source, and a second storage top electrode is provided on the second top drain.

11. The SRAM unit according to claim 10, wherein the second storage top electrode is connected to the third bottom source of the third CFET, a bottom gate of the first CFET is connected to a bottom gate of the second CFET, and the second top drain of the second CFET is connected to the third top drain of the third CFET.

12. A complementary field-effect transistor, comprising:
a substrate;
a first top source, a first top drain, a first top channel structure, a second top source, a second top drain, a second top channel structure, a first bottom source, a first bottom drain, a first bottom channel structure, a second bottom source, a second bottom drain, and a second bottom channel structure which are provided on a side of the substrate, wherein a first-type work function layer is provided on surface of the nanosheets comprised in the first top channel structure and the first bottom channel structure, and a second-type work function layer is provided on surfaces of the nanosheets comprised in the second top channel structure and the second bottom channel structure; and
a gate surrounding the nanosheets;
wherein a ground connection layer is provided on the first bottom source, a first storage bottom electrode is provided on the first bottom drain and the second bottom source, a power connection layer is provided on the second bottom drain, a buried power connection layer is electrically connected to the power connection layer, a buried ground connection layer is electrically connected to the ground connection layer, the first storage bottom electrode is electrically connected to the first bottom drain and the second bottom source, a first storage top electrode is provided on the first top drain, and the first storage top electrode is electrically connected to the first storage bottom electrode, a top power connection layer is provided on the second top source, and a second storage top electrode is provided on the second top drain.

13. The complementary field-effect transistor according to claim 12, wherein the first-type work function layer is an N-type work function layer, and the second-type work function layer is a P-type work function layer, and
wherein materials of the first top source and the first bottom source at least comprise Si, Si:C, or Si:P, and materials of the first top drain and the first bottom drain at least comprise SiGe, Si:B, or Ge.

14. A static random-access memory, comprising a plurality of storage units, wherein each of the plurality of storage units comprises the complementary field-effect transistor according to claim 12.

15. A method for manufacturing a complementary field-effect transistor, comprising:
providing a substrate, forming a plurality of stacked structures on a side of the substrate by alternately stacking first semiconductor layers and second semiconductor layers, wherein in a direction perpendicular to a plane where the substrate is located, each of the plurality of stacked structures comprises a buffer layer in a middle region;
etching the stacked structures and a partial thickness of the substrate to form two fin structures, wherein each of the fin structures comprises a top structure, a bottom structure, and a substrate structure, the top structure and the bottom structure is separated by the buffer layer, the fin structures comprise a first fin structure and a second fin structure, a buried power connection layer is provided between the substrate structure of the first fin structure and the substrate structure of the second fin structure, and a buried ground connection layer is provided on a side of the substrate structure of the first fin structure that is away from the second fin structure;
etching the top structure and the buffer layer, to form a top source region and a top drain region, wherein a top channel region is provided between the top source region and the top drain region; forming a third spacer on a sidewall of the top structure, etching the bottom structure by using the third spacer as a mask, to form a bottom source region and a bottom drain region, wherein a bottom channel region is provided between the bottom source region and the bottom drain region;
forming a first bottom source in a bottom source region of the first fin structure, forming a first bottom drain in a bottom drain region of the first fin structure, forming a second bottom source in a bottom source region of the second fin structure, and forming a second bottom drain in a bottom drain region of the second fin structure;
forming a ground connection layer on the first bottom source, forming a first storage bottom electrode on the first bottom drain and the second bottom source, forming a power connection layer on the second bottom drain, wherein the buried power connection layer is electrically connected to the power connection layer, the buried ground connection layer is electrically connected to the ground connection layer, and the first storage bottom electrode is electrically connected to the first bottom drain and the second bottom source;
forming a first top source and a first top drain on the ground connection layer and the first storage bottom electrode of the first fin structure, and forming a second top source and a second top drain on the power connection layer and the first storage bottom electrode of the second fin structure;
removing the first semiconductor layer in the top channel region and the bottom channel region, to form a plurality of to-be-filled gaps between the second semiconductor layers;
forming a first-type work function layer in the to-be-filled gaps of the first fin structure, and forming a second-type work function layer in the to-be-filled gaps of the second fin structure; filling the plurality of to-be-filled gaps with a gate, wherein the gate surrounds the second semiconductor layers, and a top channel structure and a bottom channel structure are respectively formed by a stack of a plurality of the second semiconductor layers; and
forming a first storage top electrode on the first top drain, wherein the first storage top electrode is electrically connected to the first storage bottom electrode; forming a top power connection layer on the second top source, and forming a second storage top electrode on the second top drain.

16. The method according to claim 15, wherein the forming a first bottom source in a bottom source region of the first fin structure, forming a first bottom drain in a bottom drain region of the first fin structure, forming a second bottom source in a bottom source region of the second fin structure, and forming a second bottom drain in a bottom drain region of the second fin structure, comprises:
forming a first epitaxial barrier layer on the second fin structure, forming the first bottom source in the bottom source region of the first fin structure, and forming the first bottom drain in the bottom drain region of the first fin structure;
removing the first epitaxial barrier layer, forming a second epitaxial barrier layer on the first fin structure, forming the second bottom source in the bottom source region of the second fin structure, and forming the second bottom drain in the bottom drain region of the second fin structure; and
removing the second epitaxial barrier layer.

17. The method according to claim 15, wherein before the forming a ground connection layer on the first bottom source, forming a first storage bottom electrode on the first bottom drain and the second bottom source, forming a power connection layer on the second bottom drain, the method further comprises:
forming a first dielectric layer, wherein the first dielectric layer overlays the top structure; and
etching the first dielectric layer on both sides of the top structure to form a first groove, wherein the first bottom source, the first bottom drain, the second bottom source, and the second bottom drain are exposed by the first groove; and
wherein the forming a ground connection layer on the first bottom source, forming a first storage bottom electrode on the first bottom drain and the second bottom source, forming a power connection layer on the second bottom drain, comprises:
forming the ground connection layer on the first bottom source exposed by the first groove, forming the first storage bottom electrode on the first bottom drain and the second bottom source that are exposed by the first groove, and forming the power connection layer on the second bottom drain exposed by the first groove;
wherein the method further comprises:
forming a second dielectric layer in the first groove; and
etching the first dielectric layer and the second dielectric layer such that surfaces of the first dielectric layer and the second dielectric layer that are opposite to the substrate are flush with a surface of the buffer layer opposite to the substrate;
wherein the forming a first top source and a first top drain on the ground connection layer and the first storage bottom electrode of the first fin structure, and forming a second top source and a second top drain on the power connection layer and the first storage bottom electrode of the second fin structure, comprises:
forming the first top source and the first top drain on the first dielectric layer and the second dielectric layer of the first fin structure, forming the second top source and the second top drain on the first dielectric layer and the second dielectric layer of the second fin structure, wherein the first dielectric layer and the second dielectric layer overlay the ground connection layer and the first storage bottom electrode of the first fin structure and overlay the power connection layer and the first storage bottom electrode of the second fin structure.

18. The method according to claim 15, wherein the forming a first-type work function layer in the to-be-filled gaps of the first fin structure, and forming a second-type work function layer in the to-be-filled gaps of the second fin structure, comprises:
forming the second-type work function layer in the to-be-filled gaps of the first fin structure and the to-be-filled gaps of the second fin structure;
forming a first isolation protective layer on the second fin structure, and removing the second-type work function layer in the to-be-filled gaps of the first fin structure;
forming the first-type work function layer in the to-be-filled gaps of the first fin structure; and
removing the first isolation protective layer.

19. The method according to claim 15, wherein before the forming a first storage top electrode on the first top drain, wherein the first storage top electrode is electrically connected to the first storage bottom electrode; forming a top power connection layer on the second top source, and forming a second storage top electrode on the second top drain, the method further comprises:
forming a third dielectric layer on the first top source, the first top drain, the second top source, and the second top drain; and
etching the third dielectric layer to form a second groove, wherein the first top drain, the second top drain, and the second top source are exposed by the second groove;
wherein the forming a first storage top electrode on the first top drain, wherein the first storage top electrode is electrically connected to the first storage bottom electrode; forming a top power connection layer on the second top source, and forming a second storage top electrode on the second top drain, comprises:
forming the first storage top electrode on the first top drain exposed by the second groove, forming the top power connection layer on the second top source exposed by the second groove, and forming the second storage top electrode on the second top drain exposed by the second groove.

20. The method according to claim 15, wherein before the etching the top structure and the buffer layer, the method further comprises:
forming a dummy gate and a second spacer, wherein the second spacer is located on both sides of the dummy gate;
wherein the etching the top structure and the buffer layer, to form a top source region and a top drain region, comprises:
etching the top structure and the buffer layer by using the dummy gate and the second spacer as a mask, to form the top source region and the top drain region.
